(19) United States
(12) Patent Application Publication
(10) Pub. No.: US 2026/0305136 A1
(43) Pub. Date: Oct. 1, 2026

(54) ELECTRONIC APPARATUS AND METHOD OF MANUFACTURING THE SAME

(71) Applicant: Samsung Display Co., Ltd., Yongin-si (KR)

(72) Inventors: KIHYUN KIM, Yongin-si (KR); SUNGHWAN YOUN, Yongin-si (KR)

(21) Appl. No.: 19/632,095

(22) Filed: Mar. 27, 2026

(30) Foreign Application Priority Data
Mar. 31, 2025 (KR) 10-2025-0041724

(51) Int. Cl. H10K 59/80; H10K 59/12; H10K 59/65; H10K 102/00

(52) U.S. Cl. CPC H10K 59/873; H10K 59/1201; H10K 59/65; H10K 2102/351

(57) ABSTRACT

An electronic apparatus includes an electronic panel defining a through-hole and an electronic module overlapping the through-hole in a plan view. The electronic panel includes a substrate, a circuit element layer on the substrate, a display element layer on the circuit element layer, an encapsulation layer covering the display element layer, a sensor layer on the encapsulation layer and including a plurality of sensor electrodes and a sensor cover layer covering the sensor electrodes, and a cover layer on the sensor layer and including an organic material. The through-hole passes through the substrate, the circuit element layer, the display element layer, the encapsulation layer, the sensor layer, and the cover layer, and the cover layer includes a body and a first surface between the body and the sensor layer and having a silicon content higher than that of the body.

### CROSS-REFERENCE TO RELATED APPLICATION

The present application claims priority to and the benefit of Korean Patent Application No. 10-2025-0041724, filed on Mar. 31, 2025, in the Korean Intellectual Property Office, the entire content of which is incorporated herein by reference.

### BACKGROUND

### 1. Field

Embodiments of the present disclosure relate to an electronic apparatus and a method of manufacturing the same, and for example, to an electronic apparatus including a through-hole and a method of manufacturing the same.

### 2. Description of the Related Art

Electronic apparatuses are devices that may be activated in response to electrical signals. Electronic apparatuses may include devices having various electronic components, such as a display panel for displaying images and a sensing unit for sensing external inputs. The electronic components may be electrically connected to each other by signal lines that are arranged in various manners within the apparatus.

A display panel may include light-emitting elements for generating images. A sensing unit may include sensing electrodes for sensing external inputs. The light-emitting element may be vulnerable to moisture and/or oxygen and may therefore be easily damaged without adequate protection. Accordingly, when ingress of moisture and/or oxygen from outside the display panel is reliably blocked, the reliability of electronic apparatuses may be improved and its operational lifespan may increase.

The above information disclosed in this Background section is intended to enhance understanding of the background of the disclosure and may contain information that does not constitute prior art

### SUMMARY

Aspects of one or more embodiments of the present disclosure provide an electronic apparatus having improved reliability and a method of manufacturing the same.

Additional aspects will be set forth in part in the description which follows and, in part, will be apparent from the description, or may be learned by practice of the presented embodiments of the disclosure.

One or more embodiments of the present disclosure provides an electronic apparatus including an electronic panel defining a through-hole and an electronic module overlapping the through-hole in a plan view, wherein the electronic panel includes a substrate, a circuit element layer arranged on the substrate, a display element layer arranged on the circuit element layer, an encapsulation layer covering the display element layer, a sensor layer arranged on the encapsulation layer and including a plurality of sensor electrodes and a sensor cover layer covering the plurality of sensor electrodes, and a cover layer arranged on the sensor layer and including an organic material, and wherein the through-hole passes through the substrate, the circuit element layer, the display element layer, the encapsulation layer, the sensor layer, and the cover layer, and the cover layer includes a body and a first surface arranged between the body and the sensor layer and having a silicon content (e.g., amount or atomic percentage) higher than that of the body.

In one or more embodiments, the first surface of the cover layer may be in contact with the sensor cover layer.

In one or more embodiments, the first surface of the cover layer may have a silicon content (e.g., amount or atomic percentage) higher than that of the sensor cover layer.

The electronic apparatus may further include an upper layer arranged on the cover layer and including an organic material, wherein the cover layer further includes a second surface in contact with the upper layer and the second surface may have a silicon content (e.g., amount or atomic percentage) higher than that of the body.

In one or more embodiments, the upper layer may include a side surface defining an opening through which the cover layer is at least partially exposed, and the second surface of the cover layer may not overlap the opening.

In one or more embodiments, the first surface of the cover layer may have a closed line shape around (e.g., surrounding) the through-hole.

In one or more embodiments, the first surface of the cover layer may have a shape completely overlapping the encapsulation layer.

In one or more embodiments, a silicon content (e.g., amount or atomic percentage) of the body may be less than or equal to about 0.1 atomic percent.

In one or more embodiments, the first surface of the cover layer may further include phosphorus, and the first surface of the cover layer may have a phosphorus content (e.g., amount or atomic percentage) higher than that of the body.

In one or more embodiments, a thickness of the first surface of the cover layer may be about 20 nm or less.

In one or more embodiments, the sensor cover layer may include an organic material.

The electronic apparatus may further include at least one of a processor, memory, or a power module.

In one or more embodiments, the electronic apparatus may correspond to (e.g., may be) a television, a monitor, an outdoor advertising board, a personal computer (PC), a laptop computer, a personal digital terminal, an automobile instrument panel, a center fascia, a navigation unit, a room mirror display, a game console, a smartphone, a tablet PC, a smart watch, smart glasses, a head-mounted display, or a camera.

In one or more embodiments of the present disclosure, an electronic apparatus includes an electronic panel defining a through-hole and an electronic module overlapping the through-hole in a plan view, wherein the electronic panel includes a substrate, a circuit element layer arranged on the substrate, a display element layer arranged on the circuit element layer, an encapsulation layer covering the display element layer, a sensor layer arranged on the encapsulation layer and including a plurality of sensor electrodes and a sensor cover layer covering the plurality of sensor electrodes, a cover layer arranged on the sensor layer, and an upper layer arranged on the cover layer, wherein the through-hole passes through the substrate, the circuit element layer, the display element layer, the encapsulation layer, the sensor layer, and the cover layer, and wherein the cover layer includes a body including an organic material, a first surface arranged below the body and in contact with the sensor cover layer, the first surface having a silicon content (e.g., amount or atomic percentage) higher than that of the body, and a second surface arranged above the body and in contact with the upper layer, the second surface having a silicon content (e.g., amount or atomic percentage) higher than that of the body.

In one or more embodiments, the upper layer may include an organic material.

In one or more embodiments, the first surface and the second surface of the cover layer may each have different shapes from the body in the plan view.

In one or more embodiments, the first surface and the second surface of the cover layer may each be around (e.g., surround) the through-hole in the plan view.

In one or more embodiments, the first surface and the second surface of the cover layer may each further include phosphorus, and the first surface and the second surface of the cover layer may each have a higher phosphorus content (e.g., amount or atomic percentage) than the body.

In one or more embodiments of the present disclosure, a method of manufacturing an electronic apparatus includes forming, on a substrate, a display element layer including an organic light-emitting element, forming an encapsulation layer on the display element layer, forming a plurality of sensor electrodes on the encapsulation layer, forming a sensor cover layer covering the plurality of sensor electrodes, forming an organic film on the sensor cover layer, and photo-curing the organic film so that a first surface is formed at a boundary surface between the sensor cover layer and a region of the organic film which is in contact with the sensor cover layer, wherein, in the photo-curing of the organic film, oxygen is not supplied.

In one or more embodiments, the forming of the organic film may include an inkjet printing process.

Thus, according to embodiments of the present disclosure, a cover layer of an electronic panel may include a lower and/or upper surface with a higher concentration (e.g. higher atomic percentage) of silicon and/or phosphorus to improve the adhesive strength between the cover layer and the layer above and/or below it, thereby reducing the likelihood of the cover layer peeling from the electronic panel when a hole is formed (e.g., a hole for an electronic module such as a camera) in the electronic panel.

### BRIEF DESCRIPTION OF THE DRAWINGS

The accompanying drawings are included to provide a further understanding of the present disclosure, and are incorporated in and constitute a part of this specification. The drawings illustrate embodiments of the present disclosure and, together with the description, serve to explain principles of the present disclosure. In the drawings:

FIG. 1 is a block diagram of an electronic apparatus according to one or more embodiments of the present disclosure;

FIG. 2 shows schematic diagrams of electronic apparatuses according to various embodiments of the present disclosure;

FIG. 3A is a perspective view of an electronic apparatus according to one or more embodiments of the present disclosure;

FIG. 3B is a plan view of an electronic apparatus according to one or more embodiments of the present disclosure;

FIG. 4 is a block diagram of an electronic apparatus according to one or more embodiments of the present disclosure;

FIG. 5 is a schematic cross-sectional view of an electronic apparatus according to one or more embodiments of the present disclosure;

FIG. 6 is a block diagram illustrating some components of an electronic apparatus according to one or more embodiments of the present disclosure;

FIG. 7 is an equivalent circuit diagram of a pixel of the electronic apparatus according to one or more embodiments of the present disclosure;

FIG. 8 is a cross-sectional view of an electronic panel of the electronic apparatus according to one or more embodiments of the present disclosure;

FIG. 9 is an enlarged plan view showing the region AA of FIG. 3A, according to one or more embodiments of the present disclosure;

FIGS. 10A and 10B are each an enlarged cross-sectional view taken along the line I-I′ of FIG. 9, according to one or more embodiments of the present disclosure;

FIG. 11A is a schematic cross-sectional view showing a process of a peel strength measurement test on a cover layer of a display panel, according to one or more embodiments of the present disclosure;

FIG. 11B is a bar graph showing results of a peel strength test for a comparative example and for an example according to embodiments of the present disclosure;

FIG. 12A is a schematic cross-sectional view showing a transmission electron microscope (TEM) image of a boundary between a sensor cover layer and a cover layer of a display panel according to a comparative example;

FIG. 12B is a schematic cross-sectional view showing a transmission electron microscope (TEM) image of a boundary between a sensor cover layer and a cover layer of a display panel according to one or more embodiments of the present disclosure;

FIG. 13A is a graph showing the results of a composition analysis of a cover layer according to a comparative example;

FIG. 13B is a graph showing the results of a composition analysis of a cover layer according to one or more embodiments of the present disclosure;

FIGS. 14A and 14B are cross-sectional views showing part of a method of manufacturing the cover layer of a display panel, according to one or more embodiments of the present disclosure;

FIGS. 15A-15C are cross-sectional views showing part of a method of manufacturing a cover layer of a display panel, according to one or more embodiments of the present disclosure; and

FIG. 16 is a plan view of a display panel according to one or more embodiments of the present disclosure.

### DETAILED DESCRIPTION

The present disclosure may be modified in many alternate forms, and thus specific embodiments will be illustrated in the drawings and described in more detail. It should be understood, however, that this is not intended to limit the present disclosure to the particular forms disclosed, but rather, is intended to cover all modifications, equivalents, and alternatives falling within the spirit and scope of the present disclosure.

Hereinafter, example embodiments will be described in more detail with reference to the accompanying drawings. The present disclosure, however, may be embodied in various different forms, and should not be construed as being limited to only the illustrated embodiments herein. Rather, these embodiments are provided as examples so that this disclosure will be thorough and complete, and will fully convey the aspects and features of the present disclosure to those skilled in the art. Accordingly, processes, elements, and techniques that are not necessary to those having ordinary skill in the art for a complete understanding of the aspects and features of the present disclosure may not be described.

It will be understood that when an element, such as an area, layer, film, region or portion, is referred to as being “on,” “connected to,” or “coupled to” another element, it can be directly on, connected to, or coupled to the other element, or one or more intervening elements may be present. In contrast, when an element or layer is referred to as being “directly on,” “directly connected to”, “directly coupled to”, or “immediately adjacent to” another element or layer, there are no intervening elements or layers present. In addition, it will also be understood that when an element is referred to as being “between” two elements, it can be the only element between the two elements, or one or more intervening elements may also be present.

Unless otherwise noted, like reference numerals denote like elements throughout the attached drawings and the written description, and thus, duplicative descriptions thereof may not be provided. In the drawings, the relative sizes (e.g., including lengths, widths and thicknesses) of elements, layers, and regions may be exaggerated for clarity.

As used herein, the term “and/or” includes any and all combinations of one or more of the associated listed items.

It will be understood that, although the terms “first,” “second,” “third,” etc., may be used herein to describe various elements, components, regions, layers and/or sections, these elements, components, regions, layers and/or sections should not be limited by these terms. These terms are used to distinguish one element, component, region, layer or section from another element, component, region, layer or section. Thus, a first element, component, region, layer or section described below could be termed a second element, component, region, layer or section, without departing from the spirit and scope of the present disclosure.

As used herein, the singular forms “a,” “an” and “the” are intended to include the plural forms as well, unless the context clearly indicates otherwise.

Spatially relative terms, such as “on,” “below,” “lower,” “under,” “above,” “upper,” and the like, may be used herein for ease of explanation to describe one element or feature's relationship to another element(s) or feature(s) as illustrated in the figures. It will be understood that the spatially relative terms are intended to encompass different orientations of the device in use or in operation, in addition to the orientation depicted in the drawings. For example, if the device in the figures is turned over, elements described as “below” or “beneath” or “under” other elements or features would then be oriented “above” the other elements or features. Thus, the example terms “below” and “under” can encompass both an orientation of above and below. The device may be otherwise oriented (e.g., rotated 90 degrees or at other orientations) and the spatially relative descriptors used herein should be interpreted accordingly.

Unless otherwise defined, all terms (including technical and scientific terms) used herein have the same meaning as commonly understood by one of ordinary skill in the art to which the present disclosure belongs. It will be further understood that terms, such as those defined in commonly used dictionaries, should be interpreted as having a meaning that is consistent with their meaning in the context of the relevant art and/or the present specification, and will not be interpreted in an idealized or overly formal sense unless expressly so defined herein.

It will be further understood that the terms “comprises,” “comprising,” “includes,” “including,” “have,” and “having,” when used in this specification, specify the presence of the stated features, integers, steps, operations, elements, and/or components, but do not preclude the presence or addition of one or more other features, integers, steps, operations, elements, components, and/or groups thereof. Additionally, the terms “comprise(s)/comprising,” “include(s)/including,” “have/has/having” or similar terms include or support the terms “consisting of” and “consisting essentially of,” indicating the presence of stated features, integers, steps, operations, elements, and/or components, without or essentially without the presence of other features, integers, steps, operations, elements, components, and/or groups thereof.

Unless otherwise apparent from the disclosure, expressions such as “at least one of,” “a plurality of,” “one of,” and other prepositional phrases, when preceding a list of elements, should be understood as including the disjunctive if written as a conjunctive list and vice versa. For example, the expressions “at least one of a, b, or c,” “at least one of a, b, and/or c,” “one selected from the group consisting of a, b, and c,” “at least one selected from among a, b, and c,” “at least one from among a, b, and c,” “one from among a, b, and c”, “at least one of a to c” indicates only a, only b, only c, both a and b, both a and c, both b and c, all of a, b, and c, or variations thereof.

As used herein, the terms “use,” “using,” and “used” may be considered synonymous with the terms “utilize,” “utilizing,” and “utilized,” respectively.

Hereinafter, embodiments of the present disclosure are described with reference to the drawings.

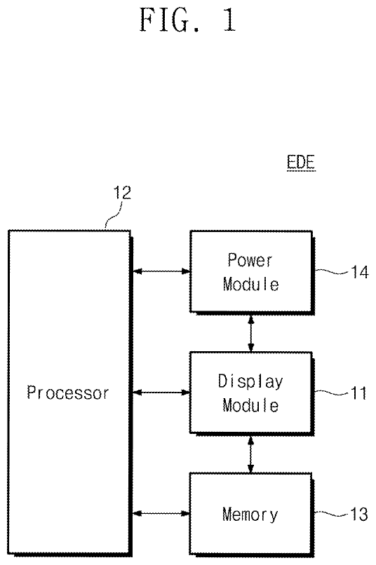

FIG. 1 is a perspective view of an electronic apparatus EDE according to one or more embodiments of the present disclosure.

Referring to FIG. 1, the electronic apparatus EDE according to one or more embodiments may include a display module 11, a processor 12, memory 13, and a power supply module 14.

The display module 11 may display images. The images may include both dynamic and still images. The processor 12 may include at least one of a central processing unit (CPU), an application processor (AP), a graphics processing unit (GPU), a communication processor (CP), an image signal processor (ISP), or a controller. The processor 12 may be configured to control operations of the display module 11.

The memory 13 may store data information for the operation of the processor 12 and/or the display module 11. When the processor 12 executes an application stored in the memory 13, image data signals and/or input control signals may be transmitted to the display module 11, and the display module 11 may process the received signals and output image information via a display screen.

The power module 14 may include a power supply module, such as a power adapter or a battery device, and a power conversion module that converts the power supplied by the power supply module and generates power for the operation of the electronic apparatus EDE.

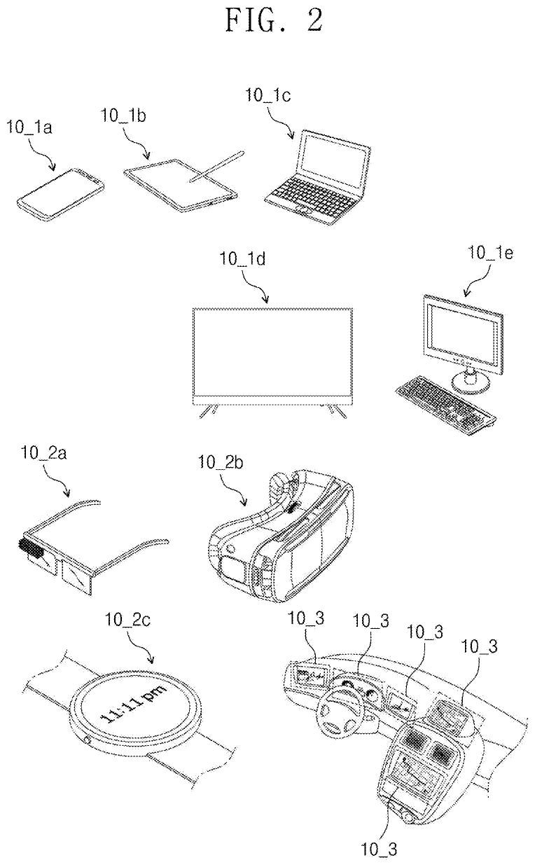

FIG. 2 shows schematic diagrams of electronic apparatuses according to various embodiments of the present disclosure.

Referring to FIG. 2, various electronic apparatuses to which the display device according to embodiments may be applied may include electronic apparatuses for displaying images, such as a smartphone 10_1a, a tablet personal computer (PC) 10_1b, a laptop 10_1c, a television (TV) 10_1d, and/or a desktop monitor 10_1e. In one or more embodiments, one or more suitable electronic apparatuses may include wearable electronic apparatuses including display modules, such as smart glasses 10_2a, a head-mounted display 10_2b, and/or a smartwatch 10_2c. Furthermore, one or more suitable electronic apparatuses may include a vehicle electronic apparatus 10_3 including display modules, such as a room mirror display and/or a center information display (CID) placed on an instrument panel, a center fascia, or a dashboard of a vehicle.

Examples of some of the electronic apparatuses according to the various embodiments are described in more detail below.

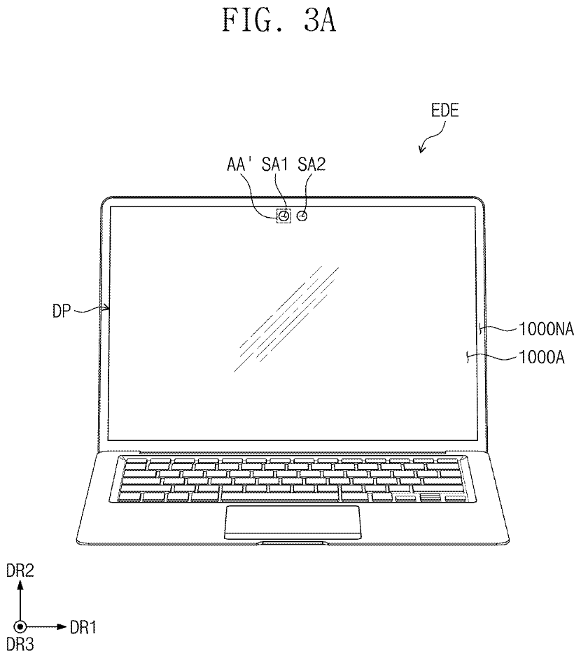

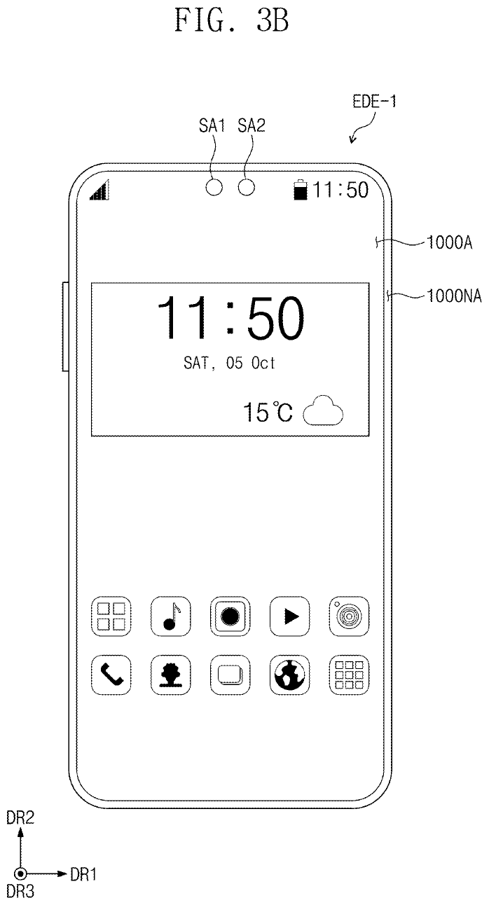

FIG. 3A is a perspective view of an electronic apparatus EDE according to one or more embodiments of the present disclosure.

Referring to FIG. 3A, the electronic apparatus EDE may be activated in response to an electrical signal. The electronic apparatus EDE may be used not only for large size electronic apparatuses, such as a TV or an outdoor advertising board, but also for small and medium size electronic apparatuses, such as a PC, a laptop computer, a personal digital terminal, an automobile navigation unit, a game console, a portable electronic appliance, or a camera. Also, the electronic apparatuses described above are only examples, and the electronic apparatus EDE may be used in other electronic apparatuses as long as these apparatuses do not deviate from scope and spirit of the present disclosure. FIG. 3A illustrates an example in which the electronic apparatus EDE is a laptop computer.

The electronic apparatus EDE may include an electronic panel DP. The electronic panel DP is a component that may generate images and it may be a display module as shown, for example, in FIG. 1. The electronic panel DP may be a light-emitting display panel, and for example, the electronic panel DP may include an organic light-emitting display panel, an inorganic light-emitting display panel, an organic-inorganic light-emitting display panel, a quantum dot display panel, a micro LED display panel, or a nano LED display panel.

Also, in one or more embodiments of the present disclosure, the electronic panel DP may further include a function of sensing an external input. For example, the electronic panel DP may be configured to sense at least one of an active input by an input device or a passive input by a touch. The touch may include inputs capable of causing a change in capacitance, such as a user's body or an input device (e.g., a pen).

An active region 1000A and a peripheral region 1000NA may be defined in the electronic panel DP. The electronic panel DP may display an image via the active region 1000A. The active region 1000A may include a surface defined by a first direction DR1 and a second direction DR2. The peripheral region 1000NA may be around (e.g., surround) the active region 1000A. In one or more embodiments of the present disclosure, the peripheral region 1000NA may not be provided.

At least one sensor region SA1 or SA2 may be defined in the active region 1000A. FIG. 3A illustrates two sensor regions SA1 and SA2, but the number of sensor regions SA1 and SA2 provided in the electronic panel DP is not limited thereto. Each of the sensor regions SA1 and SA2 may overlap at least one sensor. For example, each of the sensor regions SA1 and SA2 may overlap a front camera module, an illuminance sensor, a proximity sensor, an infrared camera, or a dot projector.

In one or more embodiments of the present disclosure, each of the sensor regions SA1 and SA2 may be a non-active region that does not display an image and does not sense a touch. In such embodiments, it may be understood that the sensor regions SA1 and SA2 are surrounded by the active region 1000A.

The thickness direction of the electronic panel DP may be parallel to the third direction DR3 that intersects the first direction DR1 and the second direction DR2. Therefore, the front surface (or the upper surface) and the rear surface (or the lower surface) of each of members constituting the electronic panel DP may be defined based on the third direction DR3.

FIG. 3B is a plan view of an electronic apparatus EDE-1 according to one or more embodiments of the present disclosure.

FIG. 3B illustrates an example in which the electronic apparatus EDE-1 has a bar-type (kind) mobile phone. FIG. 3B illustrates an example of a bar-type electronic apparatus (e.g., a bar-kind electronic apparatus) EDE-1, but the present disclosure is not limited thereto. For example, the following descriptions may be applied to one or more suitable electronic apparatuses, such as a foldable electronic apparatus EDE-1, a rollable electronic apparatus EDE-1, and/or a slidable electronic apparatus EDE-1.

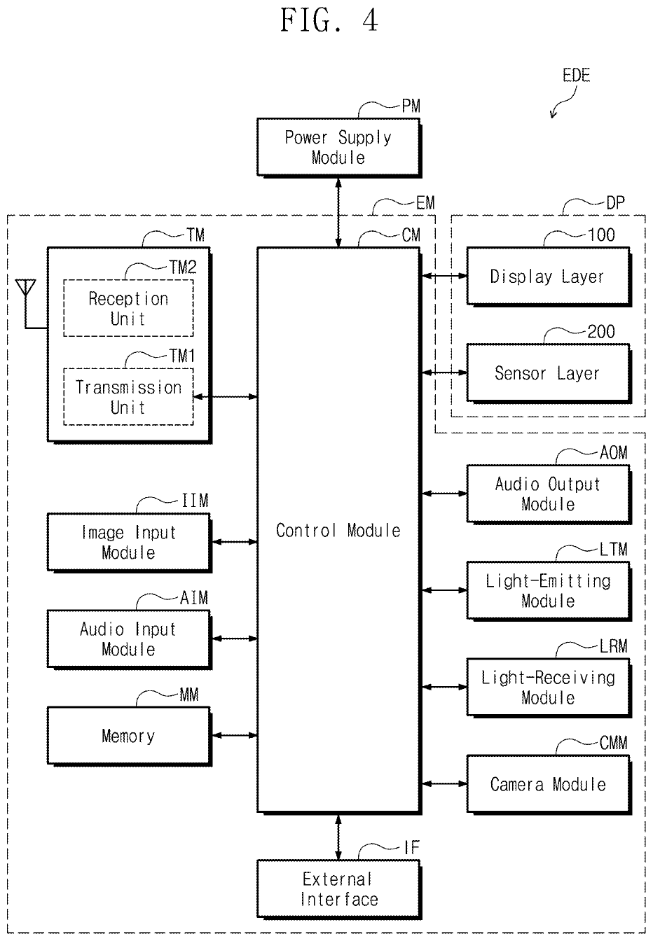

FIG. 4 is a block diagram of the electronic apparatus EDE according to one or more embodiments of the present disclosure.

Referring to FIG. 4, the electronic apparatus EDE may include an electronic panel DP, an electronic module EM, and a power supply module PM.

The electronic panel DP may include a display layer 100 and a sensor layer 200. The display layer 100 may be a component that substantially generates an image. The display layer 100 may be a light-emitting display layer, and for example, the display layer 100 may include an organic light-emitting display layer, an inorganic light-emitting display layer, an organic-inorganic light-emitting display layer, a quantum dot display layer, a micro LED display layer, or a nano LED display layer.

The sensor layer 200 may sense an external input applied from outside the electronic apparatus EDE. The external input may include an input of a user. The input of the user may include one or more suitable types (kinds) of external inputs, such as touch by a part of the user's body, light, heat, a pen, and/or pressure. In one or more embodiments of the present disclosure, the sensor layer 200 may not be provided.

The power supply module PM may supply the power for all operations of the electronic apparatus EDE. The power supply unit PM may include a general battery module.

The electronic module EM includes one or more suitable functional modules for operating the electronic apparatus EDE. The electronic module EM may be mounted directly on a motherboard electrically connected to the electronic panel DP or may be mounted on a separate substrate and electrically connected to the motherboard via a connector.

The electronic module EM may include a control module CM, a wireless communication module TM, an image input module IIM, an audio input module AIM, memory MM, an external interface IF, an audio output module AOM, a light-emitting module LTM, a light-receiving module LRM, and/or a camera module CMM.

The control module CM may control all operations of the electronic apparatus EDE. The control module CM may include a microprocessor. For example, the control module CM may activate or deactivate the electronic panel DP. The control module CM may control other modules, such as the image input module IIM or the audio input module AIM, based on a signal received from the electronic panel DP.

The wireless communication module TM may communicate with an external electronic apparatus via a first network (e.g., short-range communication networks, such as Bluetooth, WiFi direct, or infrared data association (IrDA)) or a second network (e.g., long-range communication networks, such as a cellular network, Internet, or a computer network (e.g., LAN or WAN)). Communication modules in the wireless communication module TM may be integrated into a single component (e.g., a single chip) or implemented as a plurality of separate components (e.g., a plurality of chips). The wireless communication module TM may be to transmit and receive a voice signal by using a general communication line. The wireless communication module TM may include a transmission unit TM1, which modulates a signal to be transmitted and transmits the modulated signal, and a reception unit TM2, which demodulates a received signal.

The image input module IIM may process an image signal and may convert the processed image signal into image data that may be displayed on the display panel DP. The audio input module AIM may receive an external audio signal via a microphone in a recording mode, a voice recognition mode, or other modes, and may convert the received audio signal into electrical voice data.

The external interface IF may include a connector for physically connecting the electronic apparatus EDE to an external electronic apparatus. For example, the external interface IF may include a connector, to which an external charger is inserted, a wired/wireless data port, or a card (e.g., a memory card, a SIM/UIM card) socket.

The audio output module AOM may convert audio data received from the wireless communication module TM or audio data stored in the memory MM and may then output the converted audio data to the outside.

The light-emitting module LTM may generate and output light. The light-emitting module LTM may output infrared light. The light-emitting module LTM may include an LED element. The light-receiving module LRM may sense infrared light. The light-receiving module LRM may be activated if (e.g., when) infrared light at or above a certain level is sensed. The light-receiving module LRM may include a complementary metal oxide semiconductor (CMOS) sensor. The infrared light generated in the light-emitting module LTM may be output and then reflected from an external object (e.g., the finger or face of a user). Also, the reflected infrared light may be incident onto the light-receiving module LRM.

The camera module CMM may capture still images and moving images. A plurality of camera modules CMM may be provided. Some of the camera modules CMM may overlap at least one of the sensor region SA1 or SA2 (see, e.g., FIG. 3A). An external input (e.g., light) may be provided to the camera module CMM via at least one of the sensor region SA1 or SA2. For example, the camera module CMM may capture an external image by receiving natural light via at least one of the sensor region SA1 or SA2. In one or more embodiments, the camera module CMM, and/or other electronic module EM, may overlap the sensor region SA1, SA2 and/or overlap a through-hole HA provided in the sensor region SA1, SA2, as described in more detail below.

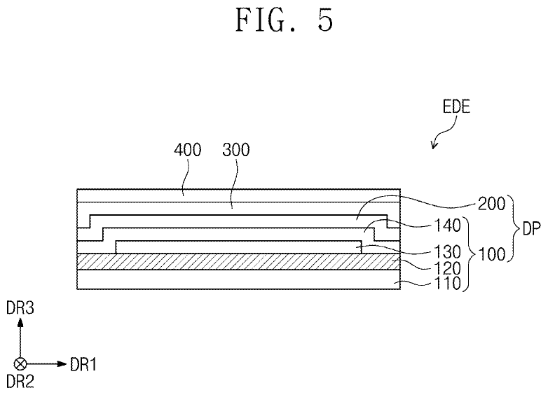

FIG. 5 is a schematic cross-sectional view of the electronic apparatus EDE according to one or more embodiments of the present disclosure.

Referring to FIG. 5, the electronic apparatus EDE may include an electronic panel DP, an anti-reflection layer 300, and a window 400. The electronic panel DP may include a display layer 100 and a sensor layer 200.

The display layer 100 may include a base layer 110, a circuit element layer 120, a display element layer 130, and an encapsulation layer 140.

The base layer 110 may include a member that provides a base surface on which the circuit element layer 120 is arranged. The base layer 110 may include a rigid substrate or a flexible substrate capable of bending, folding, rolling, and/or the like. The base layer 110 may include a glass substrate, a metal substrate, a silicon substrate, or a polymer substrate. However, the present disclosure is not limited thereto, and the base layer 110 may also include an inorganic layer, an organic layer, or a composite material layer.

The circuit element layer 120 may be arranged on the base layer 110. The circuit element layer 120 may include an insulating layer, a semiconductor pattern, a conductive pattern, a signal line, and/or the like. The insulating layer, the semiconductor layer, and the conductive layer are formed on the base layer 110 by coating, deposition, and/or the like, and then the insulating layer, the semiconductor layer, and the conductive layer may be selectively patterned by performing a photolithography process multiple times (e.g., for each layer). Subsequently, the semiconductor pattern, the conductive pattern, and the signal line, which are included in the circuit element layer 120, may be formed.

The display element layer 130 may be arranged on the circuit element layer 120. The display element layer 130 may include a light-emitting element. For example, the display element layer 130 may include an organic light-emitting material, an inorganic light-emitting material, an organic-inorganic light-emitting material, a quantum dot, a quantum rod, a micro LED, or a nano LED.

The encapsulation layer 140 may be arranged on the display element layer 130. The encapsulation layer 140 may protect the display element layer 130 from foreign substances, such as moisture, oxygen, and dust particles.

The sensor layer 200 may be arranged on the display layer 100. The sensor layer 200 may be formed on the display layer 100 by substantially continuous processes (e.g., the sensor layer 200 may include a plurality of layers that are formed in sequence on the display layer 100). In such embodiments, the sensor layer 200 may be arranged directly on the display layer 100. When the sensor layer 200 is directly arranged on the display layer 100, this may indicate that no additional component is arranged between the sensor layer 200 and the display layer 100. For example, no additional adhesive member may be provided between the sensor layer 200 and the display layer 100. Also, the sensor layer 200 may be coupled to the display layer 100 by an adhesive member. The adhesive member may include a general adhesive or bonding agent.

The anti-reflection layer 300 may be arranged on the sensor layer 200. The anti-reflection layer 300 may reduce the reflectance of external light that is incident from the outside of the electronic apparatus EDE (see, e.g., FIG. 3A). The anti-reflection layer 300 may be arranged directly on the sensor layer 200. However, the present disclosure is not limited thereto, and an adhesive member may be arranged between the anti-reflection layer 300 and the sensor layer 200.

The anti-reflection layer 300 may include color filters. The color filters may be arranged in a certain pattern. For example, the color filters may be arranged considering light-emitting colors of pixels that are included in the display layer 100. Also, the anti-reflection layer 300 may further include a black matrix that is adjacent to the color filters.

Also, the anti-reflection layer 300 may include a reflection adjustment layer. The reflection adjustment layer may selectively absorb part of the light reflected from a display panel and/or electronic equipment or the light incident from the outside of the display panel and/or electronic equipment. For example, the reflection adjustment layer may be to absorb light of wavelengths that do not belong to the red, green, or blue wavelength range emitted from the display layer 100, thereby preventing, reducing, or minimizing a decrease in the brightness of the display panel and/or electronic equipment. In one or more embodiments, deterioration in the light-emitting efficiency of the display panel and/or electronic equipment may be prevented, reduced, or minimized, and visibility may be improved.

Also, the anti-reflection layer 300 may include a phase retarder and/or a polarizer. In such embodiments, the anti-reflection layer 300 may be attached to the sensor layer 200 by an adhesive layer. The phase retarder may be of a film type (kind) or a liquid crystal coating type (kind), and may include a λ/2 phase retarder and/or a λ/4 phase retarder. The polarizer may also be of a film type (kind) and include a stretchable synthetic resin film. The phase retarder and the polarizer may further include protective films. The phase retarder and polarizer or the protective film may be defined as a base layer of the anti-reflection layer 300.

The window 400 may be arranged on the anti-reflection layer 300. An adhesive member may be located between the anti-reflection layer 300 and the window 400, but the present disclosure is not particularly limited thereto. The window 400 may include an optically transparent insulating material. For example, the window 400 may include glass or plastic. The window 400 may have a multi-layer structure or a single-layer structure. For example, the window 400 may include a plurality of plastic films, which are coupled to each other by an adhesive, or a glass substrate and a plastic film, which are coupled to each other by an adhesive.

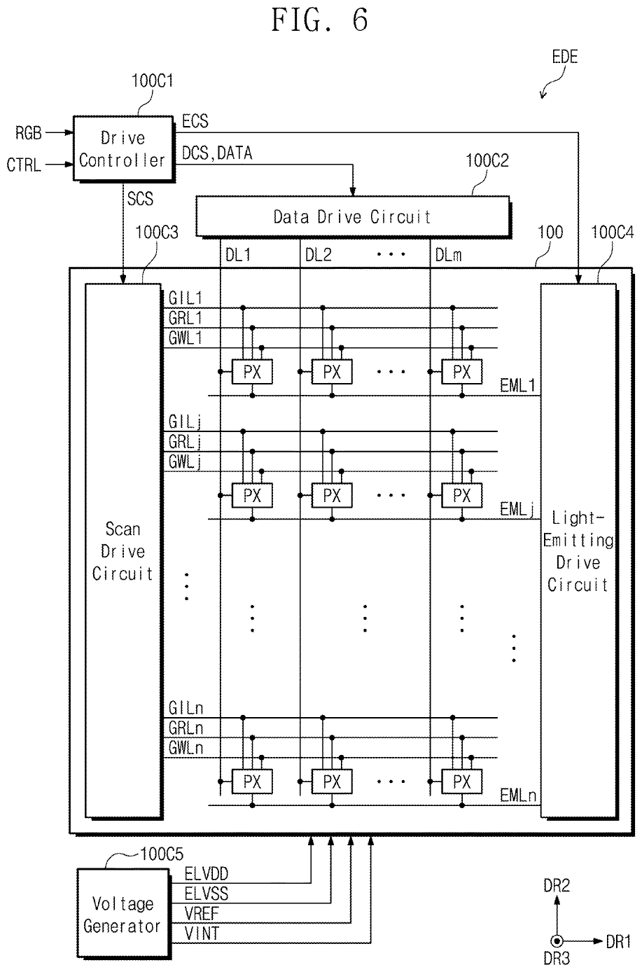

FIG. 6 is a block diagram illustrating components of the electronic apparatus EDE according to one or more embodiments of the present disclosure.

Referring to FIG. 6, the electronic apparatus EDE includes a display layer 100, a drive controller 100C1, a data drive circuit 100C2, a scan drive circuit 100C3, a light-emitting drive circuit 100C4, and a voltage generator 100C5.

The display layer 100 may include a plurality of pixels PX, scan lines GIL1 to GILn, GRL1 to GRLn, and GWL1 to GWLn, light-emitting control lines EML1 to EMLn, and data lines DL1 to DLm.

The pixels PX may be arranged in an active region of the display layer 100. Each of the plurality of pixels PX may be electrically connected to three scan lines (e.g., one of each of GIL1 to GILn, GRL1 to GRLn, and GWL1 to GWLn), one light-emitting control line EML1 to EMLn, and one data line DL1 to DLm. For example, as shown in FIG. 6, the pixels PX in a first row may be connected to the scan lines GIL1, GRL1, and GWL1 and the light-emitting control line EML1. Also, the pixels PX in a jth row may be connected to the scan lines GILj, GRLj, and GWLj and the light-emitting control line EMLj. Also, the pixels PX on the first column may be connected to the data line DL1, and pixels PX in a mth column may be connected to the data line DLm.

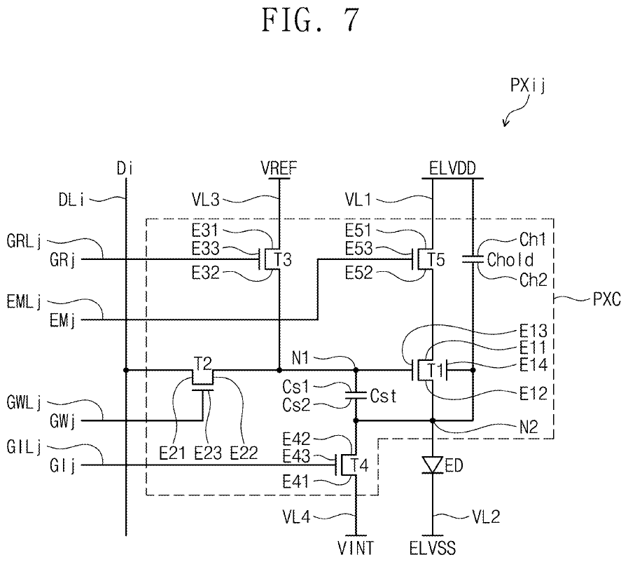

Each of the plurality of pixels PX includes a light-emitting element ED (see, e.g., FIG. 7) and a pixel circuit PXC (see, e.g., FIG. 7) for controlling the light emission of the light-emitting element ED. The pixel circuit PXC may include one or more thin-film transistors and one or more capacitors.

The scan drive circuit 100C3 and the light-emitting drive circuit 100C4 may be embedded inside the display layer 100. Therefore, the display layer 100 may include the scan drive circuit 100C3 and the light-emitting drive circuit 100C4. The scan drive circuit 100C3 and the light-emitting drive circuit 100C4 may include thin-film transistors that are formed by substantially the same process as the pixel circuit PXC.

In one or more embodiments of the present disclosure, the pixels PX may not overlap the scan drive circuit 100C3 and the light-emitting drive circuit 100C4. However, the present disclosure is not limited thereto, and at least some of the pixels PX may overlap the scan drive circuit 100C3 and the light-emitting drive circuit 100C4. In such embodiments, at least part of the scan drive circuit 100C3 and at least part of the light-emitting drive circuit 100C4 may be arranged in the display region.

The drive controller 100C1 receives an input image signal RGB and a control signal CTRL. The drive controller 100C1 generates an output image signal DATA that is obtained by converting a data format of the input image signal RGB so that the data format thereof becomes compatible with the interface specification of the data drive circuit 100C2. The drive controller 100C1 outputs a scan drive signal SCS, a data drive signal DCS, and a light-emitting drive signal ECS.

The data drive circuit 100C2 receives the data drive signal DCS and the output image signal DATA from the drive controller 100C1. The data drive circuit 100C2 converts the output image signal DATA into data signals and outputs the data signals to a plurality of data lines DL1-DLm that are described in more detail below. The data signals have analog voltages corresponding to gradation values of the output image signal DATA.

The scan drive circuit 100C3 receives the scan drive signal SCS from the drive controller 100C1. The scan drive circuit 100C3 may output scan signals to the scan lines GIL1 to GILn, GRL1 to GRLn, and GWL1 to GWLn in response to the scan drive signal SCS. The scan lines GIL1 to GILn may be referred to as first initialization scan lines GIL1 to GILn, the scan lines GRL1 to GRLn may be referred to as compensation scan lines GRL1 to GRLn, and the scan lines GWL1 to GWLn may be referred to as write scan lines GWL1 to GWLn.

The light-emitting drive circuit 100C4 receives the light-emitting drive signal ECS from the drive controller 100C1. The light-emitting drive circuit 100C4 may output light-emitting control signals to the light-emitting control lines EML1 to EMLn in response to the light-emitting drive signal ECS.

The scan drive circuit 100C3 is located on a first side of the display layer 100. The scan lines GIL1 to GILn, GRL1 to GRLn, and GWL1 to GWLn extend from the scan drive circuit 100C3 in the first direction DR1. The light-emitting drive circuit 100C4 is located on a second side of the display layer 100. The light-emitting control lines EML1 to EMLn extend from the light-emitting drive circuit 100C4 in the opposite direction to the first direction DR1.

The scan lines GIL1 to GILn, GRL1 to GRLn, and GWL1 to GWLn are spaced and/or apart (e.g., spaced apart or separated) from each other in the second direction DR2, and the light-emitting control lines EML1 to EMLn are also spaced and/or apart (e.g., spaced apart or separated) from each other in the second direction DR2. The data lines DL1 to DLm each extend from the data drive circuit 100C2 in the opposite direction to the second direction DR2 and are spaced and/or apart (e.g., spaced apart or separated) from each other in the first direction DR1.

In the electronic apparatus EDE shown in FIG. 6, the scan drive circuit 100C3 and the light-emitting drive circuit 100C4 face each other with the pixels PX therebetween, but the present disclosure is not limited thereto. For example, the scan drive circuit 100C3 and the light-emitting drive circuit 100C4 may be arranged adjacent to each other on either the first side or the second side of the display layer 100. In one or more embodiments, the scan drive circuit 100C3 and the light-emitting drive circuit 100C4 may be formed as a single circuit.

The voltage generator 100C5 generates voltages for operation of the display layer 100. In one or more embodiments, the voltage generator 100C5 generates a first drive voltage ELVDD, a second drive voltage ELVSS, a reference voltage VREF, and an initialization voltage VINT. Each of the plurality of pixels PX receives the first drive voltage ELVDD, the second drive voltage ELVSS, the reference voltage VREF, and the initialization voltage VINT from the voltage generator 100C5.

FIG. 7 is an equivalent circuit diagram of a pixel PXij according to one or more embodiments of the present disclosure. FIG. 7 illustrates an example of an equivalent circuit diagram of the pixel PXij that is connected to an ith data line DLi among the data lines DL1 to DLm (see, e.g., FIG. 6), jth scan lines GILj, GRLj, and GWLj among the scan lines GIL1 to GILn, GRL1 to GRLn, and GWL1 to GWLn (see, e.g., FIG. 6), and jth light-emitting control line EMLj among the light-emitting control lines EML1 to EMLn (see, e.g., FIG. 6). Each of the plurality of pixels PX shown in FIG. 6 may have the same circuit configuration as the equivalent circuit diagram of the pixel PXij shown in FIG. 7.

The pixel circuit PXC may include first to fifth thin-film transistors T1, T2, T3, T4, and T5, a hold capacitor Chold, and a transfer capacitor Cst. The pixel PXij shown in FIG. 7 is only one example, and the circuit configuration of the pixel PXij may be modified.

Each of the first to fifth thin-film transistors T1 to T5 may include an N-type (kind) thin-film transistor having an oxide semiconductor layer. The first thin-film transistor T1 may be referred to as a drive thin-film transistor, the second thin-film transistor T2 may be referred to as a switching thin-film transistor, the third thin-film transistor T3 may be referred to as a compensation thin-film transistor, the fourth thin-film transistor T4 may be referred to as an initialization thin-film transistor, and the fifth thin-film transistor T5 may be referred to as a light-emitting control thin-film transistor.

The scan lines GILj, GRLj, and GWLj may be to transmit scan signals GIj, GRj, and GWj, respectively, and the light-emitting control line EMLj may be to transmit a light-emitting control signal EMj. The data line DLi transmits a data signal Di. The data signal Di may have a voltage level corresponding to the input image signal RGB.

First to fourth drive voltage lines VL1 to VL4 may be to transmit, to the pixel PXij, the first drive voltage ELVDD, the second drive voltage ELVSS, the reference voltage VREF, and the initialization voltage VINT, respectively.

The first thin-film transistor T1 may include a first electrode E11 electrically connected to the first drive voltage line VL1 via the fifth thin-film transistor T5, a second electrode E12 electrically connected to an anode of the light-emitting element ED, a first gate electrode E13, and a first back gate electrode E14. A point at which the second electrode E12 of the first thin-film transistor T1 is connected to the light-emitting element ED may be defined as a second node N2.

The hold capacitor Chold is connected between the first drive voltage line VL1 and the second gate electrode E14. A first facing hold electrode Ch1 of the hold capacitor Chold is connected to the first drive voltage line VL1, and a second facing hold electrode Ch2 of the hold capacitor Chold is connected to the second gate electrode E14. In one or more embodiments of the present disclosure, the hold capacitor Chold may not be provided. Also, the first thin-film transistor T1 may not include (e.g., may exclude) the first back gate electrode E14.

The second thin-film transistor T2 includes a first electrode E21 connected to the data line DLi, a second electrode E22 connected to a first node N1, and a second gate electrode E23 connected to the scan line GWLj. In response to the scan signal GWj received via the scan line GWlj, the second thin-film transistor T2 transmits, to the first node N1, the data signal Di received via the data line DLi.

The transfer capacitor Cst is connected between the first node N1 and the second node N2. A first facing electrode Cs1 of the transfer capacitor Cst may be connected to the first node N1, and a second facing electrode Cs2 of the transfer capacitor Cst may be connected to the second node N2.

The third thin-film transistor T3 includes a first electrode E31 connected to the third drive voltage line (also referred to as a reference voltage line) VL3, a second electrode E32 connected to the first node N1, and a third gate electrode E33 connected to the scan line GRLj. The third thin-film transistor T3 may be turned on by the scan signal GRj received via the scan line GRLj and may be to transmit the reference voltage VREF to the first node N1.

The fourth thin-film transistor T4 includes a first electrode E41 connected to the fourth drive voltage line (also referred to as an initialization voltage line) VL4, a second electrode E42 connected to the second node N2, and a fourth gate electrode E43 connected to the scan line GILj. In response to the scan signal GIj received via the scan line GILj, the fourth thin-film transistor T4 may be to transmit, to the second node N2, the initialization voltage VINT received via the fourth drive voltage line VL4.

The fifth thin-film transistor T5 includes a first electrode E51 connected to the first drive voltage line VL1, a second electrode E52 connected to the first electrode E11 of the first thin-film transistor T1, and a fifth gate electrode E53 connected to the light-emitting control line EMLj. The fifth thin-film transistor T5 may be turned on by the light-emitting control signal EMj received via the light-emitting control line EMLj and may electrically connect the first drive voltage line VL1 to the first electrode E11 of the first thin-film transistor T1.

The light-emitting element ED includes an anode, which is connected to the second electrode E12 of the first thin-film transistor T1 or to the second node N2, and a cathode, which is connected to the second drive voltage line VL2.

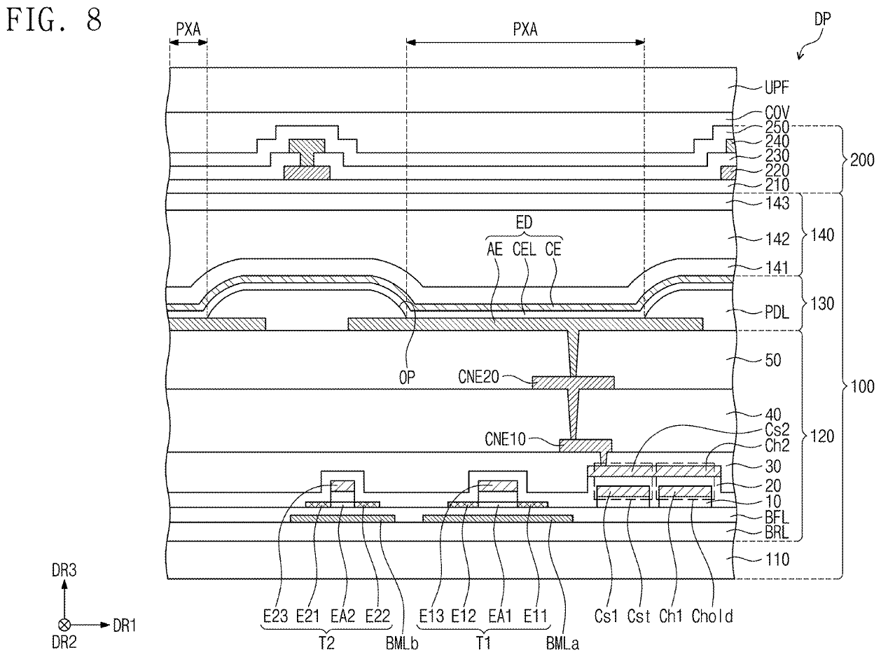

FIG. 8 is a cross-sectional view of the electronic panel DP according to one or more embodiments of the present disclosure. FIG. 8 shows components of the electronic panel DP of FIG. 5 in more detail. Referring to FIG. 8, a circuit element layer 120 may be arranged on a base layer 110. The circuit element layer 120 may include a barrier layer BRL, a buffer layer BFL, first to fifth insulating layers 10, 20, 30, 40, and 50, and the pixel circuit PXC (see, e.g., FIG. 8) which are sequentially stacked on the base layer 110. FIG. 8 illustrates an example of two thin-film transistors T1, T2 and two capacitors Cst, Chold in the pixel circuit PXC as also seen, for example, in FIG. 7.

The barrier layer BRL may be arranged on the base layer 110. The barrier layer BRL may have a single-layer structure or a multi-layer structure. The barrier layer BRL may include at least one of silicon oxide, silicon nitride, silicon oxynitride, or amorphous silicon.

Lower conductive layers BMLa, BMLb may be arranged on the barrier layer BRL. However, the present disclosure is not particularly limited thereto. For example, if (e.g., when) the barrier layer BRL has a multi-layer structure, the lower conductive layers BMLa, BMLb may be located between layers constituting the barrier layer BRL. Also, although FIG. 8 shows an example in which the lower conductive layers BMLa, BMLb are each provided as a single layer, the lower conductive layers BMLa, BMLb may each include a plurality of layers.

Each of the lower conductive layers BMLa, BMLb may include reflective metal. For example, each of the lower conductive layers BMLa, BMLb may include titanium (Ti), molybdenum (Mo), a molybdenum-containing alloy, aluminum (Al), an aluminum-containing alloy, aluminum nitride (AlN), tungsten (W), tungsten nitride (WN), copper (Cu), and/or the like. Each of the lower conductive layers BMLa, BMLb may prevent or reduce the likelihood of an electric potential caused by polarization of the base layer 110 affecting the thin-film transistors (T1, T2). Also, each of the lower conductive layers BMLa, BMLb may block or reduce light incident to the thin-film transistors T1, T2 from below.

In one or more embodiments of the present disclosure, a first lower conductive layer BMLa arranged below the first thin-film transistor T1 may be electrically separated from a second lower conductive layer BMLb arranged below the second thin-film transistor T2. For example, the first lower conductive layer BMLa arranged below the first thin-film transistor T1 may be equalized with the second electrode E12 of the first thin-film transistor T1. The second lower conductive layer BMLb arranged below the second thin-film transistor T2 may be equalized with the second gate electrode E23 of the second thin-film transistor T2. However, this is only an example, and the present disclosure is not limited thereto. For example, each of the lower conductive layers BMLa, BMLb may be independently supplied with a constant voltage or a pulse signal. Also, each of the lower conductive layers BMLa, BMLb may be provided in an isolated form from the other conductive patterns. Each of the lower conductive layers BMLa, BMLb according to one or more embodiments of the present disclosure may be provided in one or more suitable forms and is not limited to any one embodiment.

The buffer layer BFL may be arranged on the barrier layer BRL. The buffer layer BFL may prevent or reduce the likelihood of metal atoms and impurities diffusing into semiconductor patterns from the base layer 110. Also, the buffer layer BFL may control a heat supply rate during a crystallization process for forming the semiconductor patterns, and thus, the semiconductor patterns may be formed uniformly (e.g., substantially uniformly). The buffer layer BFL may include a plurality of inorganic layers. For example, the buffer layer BFL may include a first sub-buffer layer including silicon nitride and a second sub-buffer layer arranged on the first sub-buffer layer and including silicon oxide.

Semiconductor pattern layers EA1, E11, E12, EA2, E21, E22 may be arranged on the buffer layer BFL. The semiconductor pattern layers EA1, E11, E12, EA2, E21, E22 may include metal oxide. Metal oxide semiconductors may include crystalline or amorphous oxide semiconductors. For example, the oxide semiconductor may include metal oxide, such as zinc (Zn), indium (In), gallium (Ga), tin (Sn), and/or titanium (Ti), and/or a (e.g., any suitable) mixture of metal, such as zinc (Zn), indium (In), gallium (Ga), tin (Sn), and/or titanium (Ti), and oxide thereof. The oxide semiconductor may include indium-tin oxide (ITO), indium-gallium-zinc oxide (IGZO), zinc oxide (ZnO), indium-zinc oxide (IZnO), zinc-indium oxide (ZIO), indium oxide (InO), titanium oxide (TiO), indium-zinc-tin oxide (IZTO), zinc-tin oxide (ZTO), and/or the like.

The semiconductor pattern layers EA1, E11, E12, EA2, E21, E22 may include a plurality of regions that are divided according to whether the metal oxide has been reduced. A region in which the metal oxide has been reduced (hereinafter, referred to as a reduction region) has a higher conductivity than a region in which the metal oxide has not been reduced (hereinafter, referred to as a non-reduction region). The reduction region substantially functions as a source/drain for a thin-film transistor or as a signal line. The non-reduction region corresponds to a semiconductor region (or a channel) of the thin-film transistor. For example, some of the semiconductor patterns may correspond to the semiconductor region of the thin-film transistor, some of the semiconductor patterns may correspond to the source/drain of the thin-film transistor, and other semiconductor patterns may correspond to the signal transmission region.

The semiconductor pattern layers EA1, E11, E12, EA2, E21, E22 may include a first channel region EA1 of the first thin-film transistor T1 and a second channel region EA2 of the second thin-film transistor T2. The first and second channel regions EA1 and EA2 may include a non-reduction region. Each of a first electrode E11 and a second electrode E12 of the first thin-film transistor T1 may correspond to a source region or a drain region of the first thin-film transistor T1. Each of a first electrode E21 and a second electrode E22 of the second thin-film transistor T2 may correspond to a source region or a drain region of the second thin-film transistor T2. The first electrode E11 and second electrode E12 of the first thin-film transistor T1 and the first electrode E21 and second electrode E22 of the second thin-film transistor T2 may include a reduction region.

A first insulating layer 10 may be arranged on the first and second channel regions EA1 and EA2. In one or more embodiments of the present disclosure, the first insulating layer 10 may be formed to overlap only specific conductive patterns. For example, the first insulating layer 10 may be located only in a region overlapping a conductive layer directly arranged on the first insulating layer 10. FIG. 8 illustrates that the first insulating layer 10 is located only in regions overlapping the first gate electrode E13 of the first thin-film transistor T1, the second gate electrode E23 of the second thin-film transistor T2, the first facing electrode Cs1 of the transfer capacitor Cst, and the first facing hold electrode Ch1 of the hold capacitor Chold. However, the present disclosure is not particularly limited thereto. For example, the first insulating layer 10 may completely overlap the base layer 110.

The second insulating layer 20 may be arranged on the buffer layer BFL and cover the first insulating layer 10, the first gate electrode E13 of the first thin-film transistor T1, the second gate electrode E23 of the second thin-film transistor T2, the first facing electrode Cs1 of the transfer capacitor Cst, and the first facing hold electrode Ch1 of the hold capacitor Chold.

The first insulating layer 10 and the second insulating layer 20 may each be provided as an inorganic layer and have a single-layer structure or a multi-layer structure. The first insulating layer 10 and the second insulating layer 20 may each include at least one of aluminum oxide, titanium oxide, silicon oxide, silicon nitride, silicon oxynitride, zirconium oxide, or hafnium oxide. In one or more embodiments, the first insulating layer 10 and the second insulating layer 20 may each be provided as a silicon oxide layer having a single-layer structure.

The second facing electrode Cs2 of the transfer capacitor Cst and the second facing hold electrode Ch2 of the hold capacitor Chold may be arranged on the second insulating layer 20. The second facing electrode Cs2 and the second facing hold electrode Ch2 may be connected to each other to form an integrated structure.

The third insulating layer 30 may be arranged on the second insulating layer 20 and cover the second facing electrode Cs2 and the second facing hold electrode Ch2. The third insulating layer 30 may be provided as an inorganic layer and have a single-layer structure or a multi-layer structure. The third insulating layer 30 may include at least one of aluminum oxide, titanium oxide, silicon oxide, silicon nitride, silicon oxynitride, zirconium oxide, or hafnium oxide.

A first connection electrode CNE10 may be arranged on the third insulating layer 30. The first connection electrode CNE10 may be connected to the second facing electrode Cs2 via a contact hole that passes through the third insulating layer 30.

The fourth insulating layer 40 may be arranged on the third insulating layer 30. The fourth insulating layer 40 may include an organic layer. A second connection electrode CNE20 may be arranged on the fourth insulating layer 40. The second connection electrode CNE20 may be connected to the first connection electrode CNE10 via a contact hole that passes through the fourth insulating layer 40. A fifth insulating layer 50 may be arranged on the fourth insulating layer 40 and cover the second connection electrode CNE20. The fifth insulating layer 50 may include an organic layer.

The fourth insulating layer 40 and the fifth insulating layer 50 may each include general-purpose polymers, such as benzocyclobutene (BCB), polyimide, hexamethyldisiloxane (HMDSO), polymethyl methacrylate (PMMA), and/or polystyrene (PS), polymer derivatives having phenol groups, acrylic polymers, imide polymers, aryl ether polymers, amide polymers, fluorinated polymers, p-xylene polymers, vinyl alcohol polymers, and blends thereof, but the present disclosure is not particularly limited thereto.

The display element layer 130 may be arranged on the circuit element layer 120. The display element layer 130 may include light-emitting elements ED. In FIG. 8, one light-emitting element ED is shown as an example. A light-emitting region PXA may be defined corresponding to the light-emitting element ED. The light-emitting region PXA may be defined by a pixel-defining layer PDL described in more detail below.

The light-emitting element ED may include a first electrode AE, an intermediate layer CEL, and a second electrode CE. The first electrode AE may be referred to as a pixel electrode or an anode, and the second electrode CE may be referred to as a common electrode or a cathode. The intermediate layer CEL may include a functional layer shared by the pixels PX (see, e.g., FIG. 6) and a light-emitting layer patterned corresponding to each of the pixels PX.

The first electrode AE may be arranged on the fifth insulating layer 50. The first electrode AE may be connected to the second connection electrode CNE20 via a contact hole that passes through the fifth insulating layer 50. The first electrode AE may include a (semi-)transmissive electrode or a reflective electrode. In one or more embodiments, the first electrode AE may include a reflective layer, which includes silver, magnesium, aluminum, platinum, palladium, gold, nickel, neodymium, iridium, chromium, or a compound thereof, and a transparent or translucent electrode layer, which is formed on the reflective layer. The transparent or translucent electrode layer may include at least one selected from the group consisting of indium tin oxide, indium zinc oxide, indium gallium zinc oxide, zinc oxide or indium oxide, and aluminum-doped zinc oxide. For example, the first electrode AE may include a multi-layer structure in which indium tin oxide, silver, and indium tin oxide are sequentially stacked.

A pixel-defining layer PDL may be arranged on the fifth insulating layer 50. The pixel-defining layer PDL may have light absorbing characteristics, and for example, the pixel-defining layer PDL may have a black color. The pixel-defining layer PDL may include a black coloring agent. The black coloring agent may include black dye and/or black pigment. The black coloring agent may include carbon black, a metal such as chromium, or an oxide thereof. However, the materials that constitute the pixel-defining layer PDL are not limited thereto.

An opening OP, through which the first electrode AE is partially exposed, may be defined in the pixel-defining layer PDL. For example, the pixel-defining layer PDL may cover the edge of the first electrode AE. The light-emitting region PXA may be defined by the pixel-defining layer PDL.

The intermediate layer CEL may be arranged on the first electrode AE and the pixel-defining layer PDL. The intermediate layer CEL may include a first functional layer, a light-emitting layer, and a second functional layer.

The first functional layer may include a hole transport layer (HTL), a hole injection layer (HIL), or both the HTL and the HIL. The first functional layer HFL may be arranged entirely over (e.g., over an entirety of) the active region 1000A (see, e.g., FIG. 3A). Therefore, the first functional layer may be a layer shared by the pixels PX.

The light-emitting layer EML may be arranged on the first functional layer and positioned in a region overlapping the opening OP of the pixel-defining layer PDL. The light-emitting layer may include an organic material, an inorganic material, or an organic-inorganic material that emits light of a certain color.

The second functional layer may be arranged above the first functional layer and may cover the light-emitting layer. The second functional layer may include an electron transport layer (ETL), an electron injection layer (EIL), or both the ETL and the EIL. The second functional layer may be arranged entirely over (e.g., over an entirety of) the active region 1000A (see, e.g., FIG. 3A). Therefore, the second functional layer may be a layer shared by the pixels PX.

The second electrode CE may be arranged on the intermediate layer CEL. The second electrode CE may be arranged entirely over (e.g., over an entirety of) the active region 1000A (see, e.g., FIG. 3A). Therefore, the second electrode CE may be a layer shared by the pixels PX.

The encapsulation layer 140 may be arranged on the display element layer 130. The encapsulation layer 140 may include an organic layer and a plurality of inorganic layers for sealing the organic layer. For example, the encapsulation layer 140 may include a first encapsulation layer 141, a second encapsulation layer 142, and a third encapsulation layer 143 which are sequentially stacked, but the present disclosure is not particularly limited thereto. The first and third encapsulation layers 141 and 143 may protect the display element layer 130 against moisture and oxygen, and the second encapsulation layer 142 may protect the display element layer 130 against foreign substances, such as dust particles. For example, the first and third encapsulation layers 141 and 143 may include inorganic encapsulation layers, and the second encapsulation layer 142 may include an organic encapsulation layer.

The sensor layer 200 may be arranged on the display layer 100. The sensor layer 200 may be referred to as a sensor, an input sensing layer, or an input sensing panel. The sensor layer 200 may have a function of sensing an external input. For example, the sensor layer 200 may be configured to sense at least one of an active input by an input device or a passive input by a touch.

The sensor layer 200 may include a sensor base layer 210, a first sensor conductive layer 220, a sensor insulating layer 230, a second sensor conductive layer 240, and a sensor cover layer 250.

The sensor base layer 210 may be directly arranged on the display layer 100. In one or more embodiments, the sensor base layer 210 may include an organic layer. For example, the sensor base layer 210 may include epoxy resin, acrylic resin, or imide-based resin. The sensor base layer 210 may cover a curved lower surface and provide a flat surface on the upper side thereof. Accordingly, the first sensor conductive layer 220 may be stably formed on the flat surface. The sensor base layer 210 may have a single-layer structure or a multi-layer structure in which layers are stacked in the third direction DR3. The sensor base layer 210 having a multi-layer structure may include an organic layer and an inorganic layer including at least one of silicon nitride, silicon oxynitride, or silicon oxide.

The first sensor conductive layer 220 and the second sensor conductive layer 240 may each have a single-layer structure or a multi-layer structure in which layers are stacked in the third direction DR3.

A conductive layer having a single-layer structure may include a metal layer or a transparent conductive layer. The metal layer may include molybdenum, silver, titanium, copper, aluminum, or an alloy thereof. The transparent conductive layer may include transparent conductive oxide, such as indium tin oxide, indium zinc oxide, zinc oxide, or indium zinc tin oxide. In one or more embodiments, the transparent conductive layer may include conductive polymer such as PEDOT, metal nanowire, graphene, and/or the like.

A conductive layer having a multi-layer structure may include metal layers. The metal layers may have, for example, a three-layer structure of titanium/aluminum/titanium. In one or more embodiments, the conductive layer having the multi-layer structure may include at least one metal layer and at least one transparent conductive layer.

The sensor insulating layer 230 may be located between the first sensor conductive layer 220 and the second sensor conductive layer 240. The sensor cover layer 250 may be arranged on the sensor insulating layer 230 and cover the second sensor conductive layer 240. The second sensor conductive layer 240 may include a conductive pattern. The sensor cover layer 250 may cover the conductive pattern and reduce or eliminate the probability that the conductive pattern is damaged in subsequent processes.

The sensor insulating layer 230 may include an inorganic film. The sensor cover layer 250 may include an inorganic film or an organic material. For example, the sensor cover layer 250 may include an organic material such as a polyimide, acrylic, epoxy, and/or other polymeric film; in one or more other examples, the sensor insulating layer 230 and/or the sensor cover layer 250 may each include an inorganic film including at least one of aluminum oxide, titanium oxide, silicon oxide, silicon nitride, silicon oxynitride, zirconium oxide, or hafnium oxide.

The cover layer COV may be arranged on the sensor layer 200. The cover layer COV may be in contact with the sensor cover layer 250. The cover layer COV may cover a curved upper surface of the sensor cover layer 250 and provide a flat upper surface on the upper side thereof. The cover layer COV may be formed by an inkjet printing process.

An upper film UPF may be arranged on the cover layer COV. The upper film UPF may include an optically transparent insulating layer. The upper film UPF may be in contact with the cover layer COV. The upper film UPF may be provided as a film or may be provided as a coating layer. For example, the upper film UPF may include a window or an optical film attached to the cover layer COV, or include an organic layer formed directly on the cover layer COV by an inkjet printing process. However, the upper film UPF is not limited to any one embodiment.

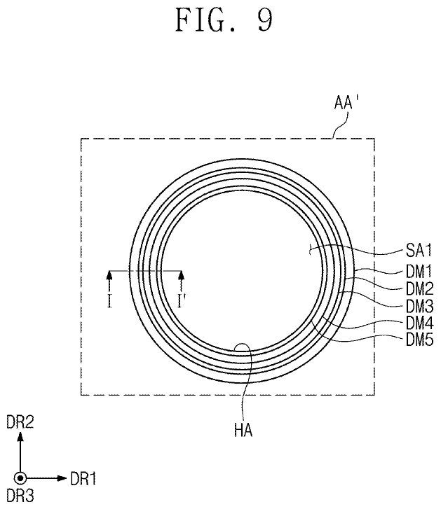

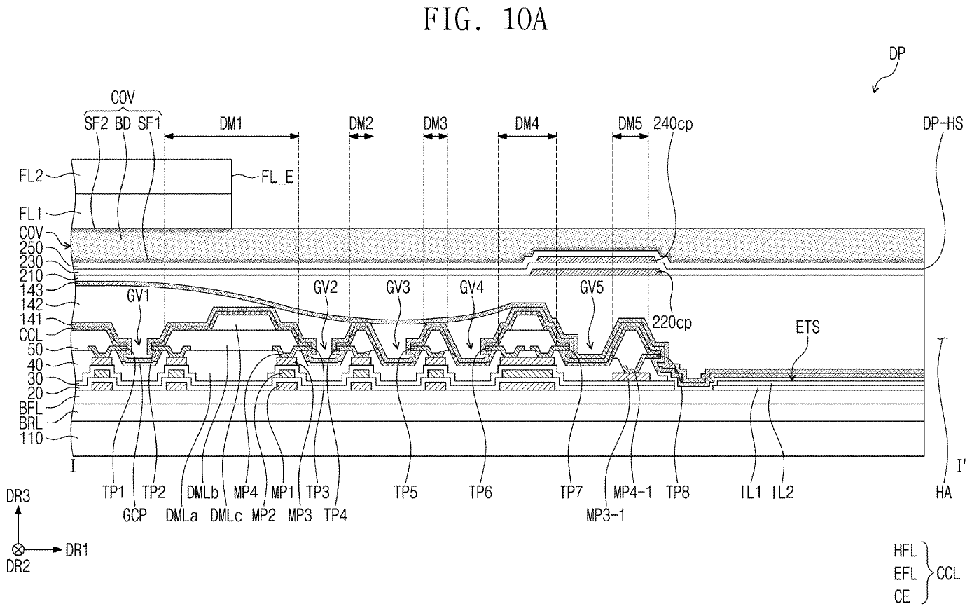

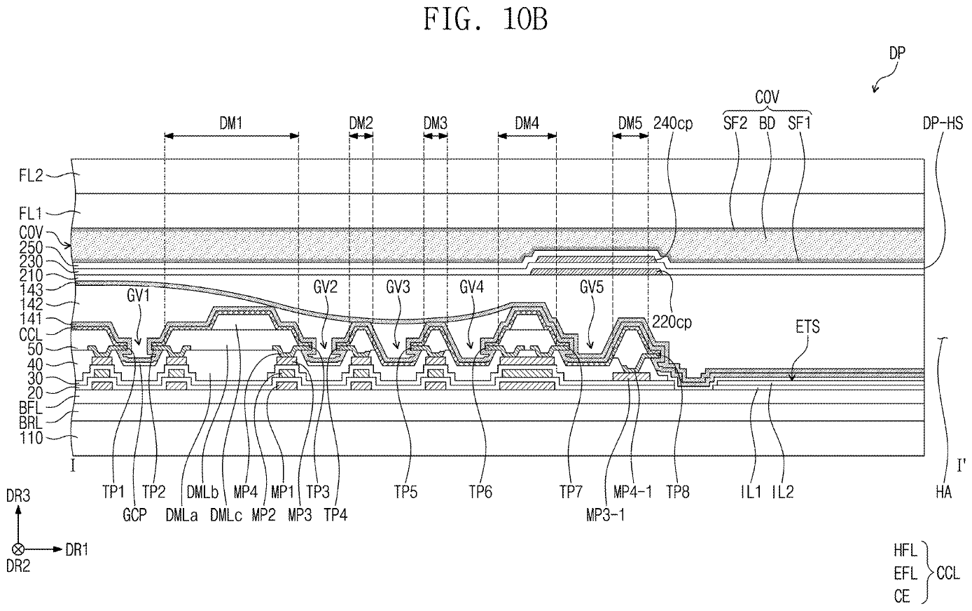

FIG. 9 is an enlarged plan view showing part of a display panel according to one or more embodiments of the present disclosure. FIGS. 10A and 10B are enlarged cross-sectional views showing part of a display panel according to one or more embodiments of the present disclosure. FIG. 9 may be an enlarged view of the AA′ region of FIG. 3A according to one or more embodiments of the present disclosure. FIGS. 10A and 10B may be cross-sectional views of a display panel taken along the line I-I′ of FIG. 9 according to one or more embodiments of the present disclosure. Hereinafter, the present disclosure is described with reference to FIGS. 9 to 10B. Here, the same reference numerals may be given to the same components as those described above with reference to FIGS. 1A to 8, and repeated descriptions thereof may not be provided.

Referring to FIG. 9, a hole HA (or a through-hole HA) is defined in the electronic panel DP. The hole HA may be defined by partially removing the electronic panel DP. The active region 1000A of the electronic panel DP may be around (e.g., surround) the hole HA. The hole HA may overlap or correspond to the sensor region SA1. In FIG. 9, the hole HA is illustrated as a circle, but the present disclosure is not limited thereto and the hole HA may have one or more suitable shapes, such as a polygon, an ellipse, a shape having at least one curved side, and/or an irregular shape. However, the shape of the hole HA is not limited to any one embodiment.

The electronic panel DP may further include a plurality of dams DM1, DM2, DM3, DM4, DM5 arranged adjacent to the hole HA. The plurality of dams DM1, DM2, DM3, DM4, DM5 may be provided to control the flow of monomer during a process of forming the second encapsulation layer 142 or to protect the display element layer 130 during a process of forming the hole HA. FIG. 9 shows an example of five dams DM1, DM2, DM3, DM4, DM5, but the present disclosure is not particularly limited thereto. Some of the five dams DM1, DM2, DM3, DM4, DM5 may not be provided, and more dams may be added.

Referring to FIGS. 10A and 10B, the electronic panel DP may include a sidewall DP-HS that defines the hole HA. The electronic panel DP may include the plurality of dams DM1, DM2, DM3, DM4, DM5 and a barrier layer ETS, which are arranged adjacent to the hole HA. FIGS. 10A and 10B illustrate an example of the five dams DM1, DM2, DM3, DM4, DM5 and the barrier layer ETS, but the present disclosure is not particularly limited thereto. For example, in the electronic panel DP according to one or more embodiments of the present disclosure, one or more of the five dams DM1, DM2, DM3, DM4, DM5 and the barrier layer ETS may not be provided, or more dams may be provided.

The dams DM1, DM2, DM3, DM4, DM5 may include a first dam DM1, a second dam DM2, a third dam DM3, a fourth dam DM4, and a fifth dam DM5. The first to fourth dams DM1, DM2, DM3, and DM4 may control the flow of monomer during the process of forming the second encapsulation layer 142. The fifth dam DM5 and the barrier layer ETS may prevent or reduce the likelihood of cracks progressing from the sidewall DP-HS. Therefore, the fifth dam DM5 may be referred to as a crack dam.

Also, the barrier layer ETS may prevent or reduce the likelihood of upper organic layers, such as the sensor base layer 210 and the cover layer COV, being damaged or deformed due to laser irradiation during an etching process for forming the hole HA. The barrier layer ETS may be formed by stacking a plurality of dam layers IL1, IL2. A first dam layer IL1 may include the same material as the second insulating layer 20 and be formed by substantially the same process as the second insulating layer 20. A second dam layer IL2 may include the same material as the third insulating layer 30 and be formed by substantially the same process as the third insulating layer 30. However, this is only one example, and the configuration of layers constituting the barrier layer ETS may be modified in any suitable manner. Also, the width of the first dam layer IL1 may be greater than the width of the second dam layer IL2 in a first and/or second direction DR1, DR2. Therefore, the side surface of the barrier layer ETS may have a stepped shape. However, this is illustrated as an example, and the shape of the side surface of the barrier layer ETS may be designed in any suitable manner and is not limited to any one embodiment.

The first dam DM1 and the fourth dam DM4 may have the highest height (or greatest thickness) among the first to fifth dams DM1, DM2, DM3, DM4, and DM5. For example, the first dam DM1 and the fourth dam DM4 may each include a first conductive layer MP1, the second insulating layer 20, a second conductive layer MP2, the third insulating layer 30, a third conductive layer MP3, a first dam layer DMLa, a fourth conductive layer MP4, a second dam layer DMLb, and a third dam layer DMLc.

The first conductive layer MP1 may be arranged at the same layer as the first gate electrode E13 of the first thin-film transistor T1, the second gate electrode E23 of the second thin-film transistor T2, the first facing electrode Cs1 of the transfer capacitor Cst, and the first facing hold electrode Ch1 of the hold capacitor Chold, and may also include the same material. The second conductive layer MP2 may be arranged at the same layer as the second facing electrode Cs2 of the transfer capacitor Cst and the second facing hold electrode Ch2 of the hold capacitor Chold, and may also include the same material. The third conductive layer MP3 may be arranged at the same layer as the first connection electrode CNE10 and may also include the same material. The fourth conductive layer MP4 may be arranged at the same layer as the second connection electrode CNE20 and may also include the same material.

The first dam layer DMLa may include the same material as the fourth insulating layer 40. The first dam layer DMLa may be provided as part of the fourth insulating layer 40. The second dam layer DMLb may include the same material as the fifth insulating layer 50. The second dam layer DMLb may be provided as part of the fifth insulating layer 50. The third dam layer DMLc may be arranged at the same layer as the pixel-defining layer PDL and may also include the same material.

The second dam DM2 and the third dam DM3 may have less height or thickness than each of the first and fourth dams DM1 and DM4. For example, the second dam DM2 and the third dam DM3 may each include the first conductive layer MP1, the second insulating layer 20, the second conductive layer MP2, the third insulating layer 30, the third conductive layer MP3, the first dam layer DMLa, the fourth conductive layer MP4, and the second dam layer DMLb.

In one or more embodiments of the present disclosure, the fourth conductive layer MP4 of each of the first to fourth dams DM1, DM2, DM3, and DM4 may be in contact with the third conductive layer MP3. For example, the continuity of the fourth insulating layer 40 may be disrupted by the third conductive layer MP3 and the fourth conductive layer MP4 that are in contact with each other. Therefore, while the hole HA is being processed, a path through which an etching solution enters may be blocked by the first to fourth dams DM1, DM2, DM3, and DM4.

The fifth dam DM5 may be located closest to the HA among the first to fifth dams DM1, DM2, DM3, DM4, and DM5. The fifth dam DM5 may include the second insulating layer 20, the third insulating layer 30, a third conductive layer MP3-1, the first dam layer DMLa, a fourth conductive layer MP4-1, and the second dam layer DMLb.

In one or more embodiments of the present disclosure, the fourth conductive layer MP4-1 of the fifth dam DM5 may be in contact with the third conductive layer MP3-1. For example, the continuity of the fourth insulating layer 40 may be disrupted by the third conductive layer MP3-1 and the fourth conductive layer MP4-1 that are in contact with each other. Therefore, while the hole HA is being processed, the path through which the etching solution enters may be further blocked by the fifth dam DM5. Therefore, the reliability of the electronic panel DP may be further improved.

Also, the electronic panel DP according to one or more embodiments of the present disclosure may include first to fifth grooves GV1, GV2, GV3, GV4, and GV5, which are defined adjacent to the first to fifth dams DM1, DM2, DM3, DM4, and DM5, respectively. In one or more embodiments of the present disclosure, the bottom surface of each of the first to fifth grooves GV1, GV2, GV3, GV4, and GV5 may be defined in the fourth insulating layer 40. Each of the first to fifth grooves GV1, GV2, GV3, GV4, and GV5 may overlap at least one tip TP1 to TP8. The tips TP1 to TP8 may be defined by inorganic insulating patterns or metal patterns that protrude toward the inside of each of the grooves GV1, GV2, GV3, GV4, and GV5.

The electronic panel DP may include a plurality of tips TP1, TP2, TP3, TP4, TP5, TP6, TP7, TP8. The tips TP1, TP2, TP3, TP4, TP5, TP6, TP7, TP8 may separate a common layer CCL formed by an open mask. For example, the common layer CCL may include a first functional layer HFL, a second functional layer EFL, and a second electrode CE. Parts of the common layer CCL separated by the plurality of tips TP1, TP2, TP3, TP4, TP5, TP6, TP7, TP8, for example, separated layers GCP, may respectively overlap the first to fifth grooves GV1, GV2, GV3, GV4, and GV5.

A first tip TP1 and a second tip TP2 may overlap the first groove GV1, a third tip TP3 and a fourth tip TP4 may overlap the second groove GV2, a fifth tip TP5 may overlap the third groove GV3, a sixth tip TP6 may overlap the fourth groove GV4, and a seventh tip TP7 may overlap the fifth groove GV5. The eighth tip TP8 may protrude in a direction toward the hole HA from the fifth dam DM5.

The first groove GV1 and the second groove GV2, which are closest to the display region among the first to fifth grooves GV1, GV2, GV3, GV4, and GV5, are provided with the maximum number of tips, and thus, the common layer CCL may be stably separated. Therefore, the reliability of the electronic panel DP may be further improved. Also, in the electronic panel DP according to one or more embodiments, the number of tips may vary and is not limited to any one embodiment.

The first encapsulation layer 141 may cover all of the first to fifth grooves GV1, GV2, GV3, GV4, and GV5. The second encapsulation layer 142 may be arranged on the first encapsulation layer 141 and overlap at least some of the first to fifth grooves GV1, GV2, GV3, GV4, and GV5. For example, the second encapsulation layer 142 may overlap the first to fourth grooves GV1, GV2, GV3, and GV4. The third encapsulation layer 143 may be arranged on the second encapsulation layer 142 and cover all of the first to fifth grooves GV1, GV2, GV3, GV4, and GV5.

In one or more embodiments of the present disclosure, the first sensor conductive layer 220 of the sensor layer 200 may include a first clad pattern 220cp, and the second sensor conductive layer 240 may include a second clad pattern 240cp. The first clad pattern 220cp and the second clad pattern 240cp may each overlap with the remaining groove (e.g., the groove closest to the hole HA) not overlapping the second encapsulation layer 142, for example, the fifth groove GV5. Also, the first clad pattern 220cp and the second clad pattern 240cp may each overlap the fifth dam DM5 (or referred to as a crack dam) and the eighth tip TP8 that protrudes from the fifth dam DM5 toward the hole HA.

The curvature of the third encapsulation layer 143 may be increased due to the fifth groove GV5 in which the second encapsulation layer 142 is not arranged. In such embodiments, the quality of film in the third encapsulation layer 143 deteriorates due to the curvature, and cracks may occur in the third encapsulation layer 143. Also, the third encapsulation layer 143 may oxidize even if (e.g., when) including silicon nitride. According to one or more embodiments of the present disclosure, the first and second clad patterns 220cp and 240cp are arranged in a region overlapping the fifth groove GV5. Therefore, even if (e.g., when) cracks occur in the third encapsulation layer 143 or the third encapsulation layer 143 oxidizes, the first and second clad patterns 220cp and 240cp may block or reduce moisture and oxygen. Therefore, the product reliability of the electronic panel DP may be improved.

Also, in the electronic panel DP according to one or more embodiments of the present disclosure, the cover layer COV may include a body BD, a first surface SF1, and a second surface SF2. The body BD, the first surface SF1, and the second surface SF2 may represent portions (or regions) that include materials with different composition ratios (or contents (e.g., amounts)) in a single layer. The body BD, the first surface SF1, and the second surface SF2 may be distinguished from each other in the thickness direction DR3 (or the third direction) in the cross-section.

The body BD may include an organic material. For example, the body BD may include carbon atoms, oxygen atoms, and nitrogen atoms.

The first surface SF1 may be located on the lower side of the body BD. For example, the first surface SF1 may be located between the body BD and the sensor cover layer 250. The first surface SF1 is in contact with the sensor cover layer 250. The coupling strength between the first surface SF1 and the sensor cover layer 250 may be greater than the coupling strength between the body BD and the sensor cover layer 250. The first surface SF1 may provide high coupling strength, thereby preventing or reducing the likelihood of a peel failure between the sensor cover layer 250 and the cover layer COV.

The first surface SF1 may have a higher silicon (Si) concentration than the body BD. The first surface SF1 may include a layer in which carbon atoms, oxygen atoms, nitrogen atoms, and silicon atoms are mixed. For example, the body BD may not include (e.g., may exclude) silicon, and the first surface SF1 may include silicon. In one or more embodiments, the body BD may include silicon, but the silicon concentration at (in) the first surface SF1 may be greater than that in the body BD. The silicon content (e.g., amount or atomic percentage) of the first surface SF1 may be about 0.1 atomic percent (at %) or more (e.g., more than about 0.1 atomic percent (at %).

Also, the first surface SF1 may have a higher phosphorus (P) concentration than the body BD. The first surface SF1 may include a layer in which carbon atoms, oxygen atoms, nitrogen atoms, silicon atoms, and phosphorus atoms are mixed. For example, the body BD may not include (e.g., may exclude) phosphorus, and the first surface SF1 may include phosphorus. In one or more embodiments, the body BD may include phosphorus, but the phosphorus concentration at (in) the first surface SF1 may be greater than that in the body BD.

The silicon atoms and phosphorus atoms may each include components that constitute a leveling agent. The silicon atoms and phosphorus atoms may each increase the coupling strength with adjacent other layers. According to one or more embodiments of the present disclosure, the peel strength of the cover layer COV may be easily controlled or selected by controlling the composition ratio of the first surface SF1.

The second surface SF2 may be located on the upper side of the body BD. For example, the second surface SF2 may be located between the body BD and upper layers FL1 and FL2. The second surface SF2 is in contact with the upper film UPF (e.g., the upper film UPF including upper layers FL1, FL2). The coupling strength between the second surface SF2 and the upper layer FL1 may be greater than the coupling strength between the body BD and the upper layer FL1. The second surface SF2 may provide high coupling strength, thereby preventing or reducing the likelihood of a peel failure between the upper layer FL1 and the cover layer COV.

The second surface SF2 may have a higher silicon (Si) concentration than the body BD. The second surface SF2 may include a layer in which carbon atoms, oxygen atoms, nitrogen atoms, and silicon atoms are mixed. For example, the body BD may not include (e.g., may exclude) silicon, and the second surface SF2 may include silicon. In one or more embodiments, the body BD may include silicon, but the silicon concentration at (in) the second surface SF2 may be greater than that in the body BD.

Also, the second surface SF2 may have a higher phosphorus (P) concentration than the body BD. The second surface SF2 may include a layer in which carbon atoms, oxygen atoms, nitrogen atoms, silicon atoms, and phosphorus atoms are mixed. For example, the body BD may not include (e.g., may exclude) phosphorus, and the second surface SF2 may include phosphorus. In one or more embodiments, the body BD may include phosphorus, but the phosphorus concentration at (in) the second surface SF2 may be greater than that in the body BD.

The second surface SF2 may have a composition ratio similar to that of the first surface SF1. For example, the second surface SF2 may have the same composition ratio as the first surface SF1, but may also have a different composition ratio from the first surface SF1. The second surface SF2 and the first surface SF1 may be formed by diffusion and concentration of materials constituting the cover layer COV, and may thus vary depending on the curing conditions or the thickness of the cover layer COV, which is described in more detail below. For example, the first surface SF1 and the second surface SF2 may each be formed by photo-curing, for example, by curing the cover layer COV at a rate of about 80 mm/sec by using ultraviolet (UV) light of about 1.5 J. Here, the thickness of the first surface SF1 or the second surface SF2 may be greater than about or equal to 1 nm and less than or equal to about 20 nm, but the present disclosure is not limited thereto. For example, in one or more embodiments, the thickness is about 20 nm or less.

The second surface SF2 may be formed at the interface in contact with the upper layers FL1 and FL2. For example, as shown in FIG. 10A, if (e.g., when) the upper layers FL1 and FL2 are partially removed such that an end FL_E of the upper layers FL1 and FL2 is formed on the cover layer COV, the second surface SF2 may be formed only at the interface in contact with the upper layers FL1 and FL2 and may not be formed in a region exposed from the upper layers FL1 and FL2. Also, as shown in FIG. 10B, if (e.g., when) the upper layers FL1 and FL2 entirely cover (e.g., cover the entirety of) the upper surface of the cover layer COV, the second surface SF2 may be entirely formed on (e.g., may be formed across the entirety of) the upper surface of the cover layer COV such that the second surface SF2 overlaps the second to fifth dams DM2, DM3, DM4, and DM5 and is adjacent to the hole HA. According to one or more embodiments the present disclosure, the second surface SF2 may be formed locally only in the region in contact with the upper layers FL1 and FL2 so as to improve the coupling strength with the upper layers FL1 and FL2, or may be formed entirely on the cover layer COV. Accordingly, a peel failure between contacting layers (250, FL1) may be effectively prevented or reduced, thereby improving product reliability.

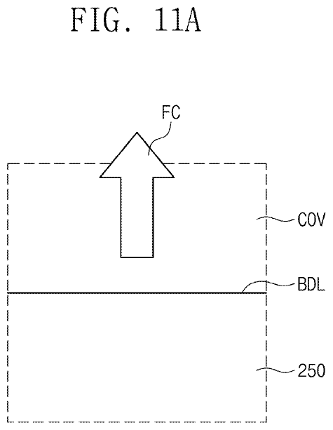

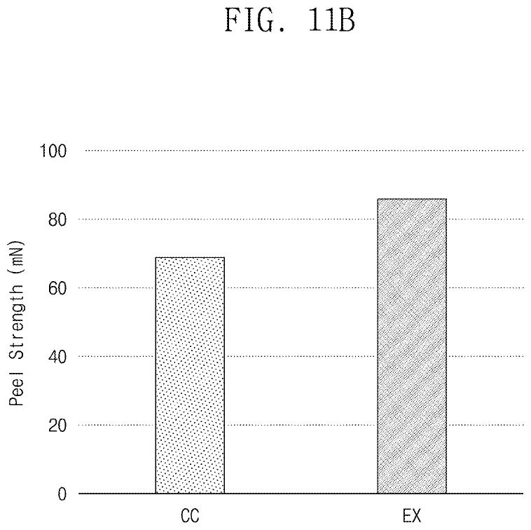

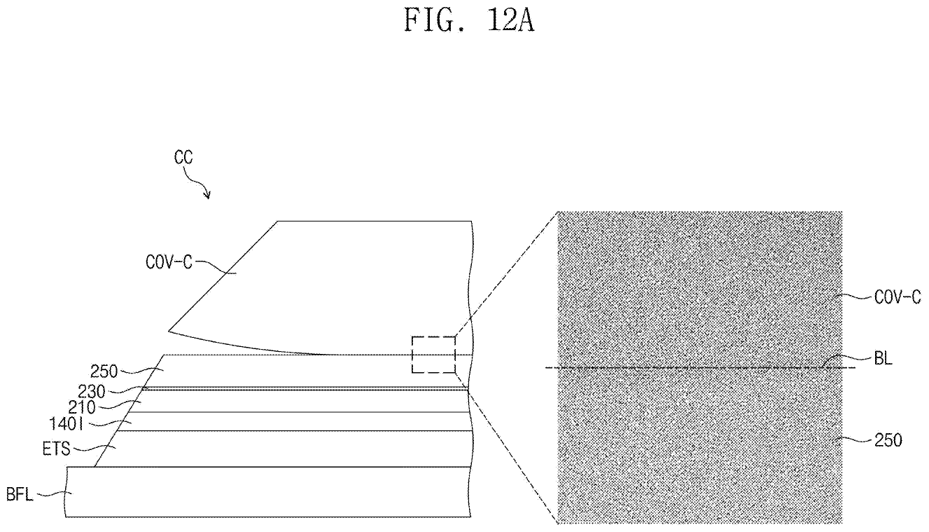

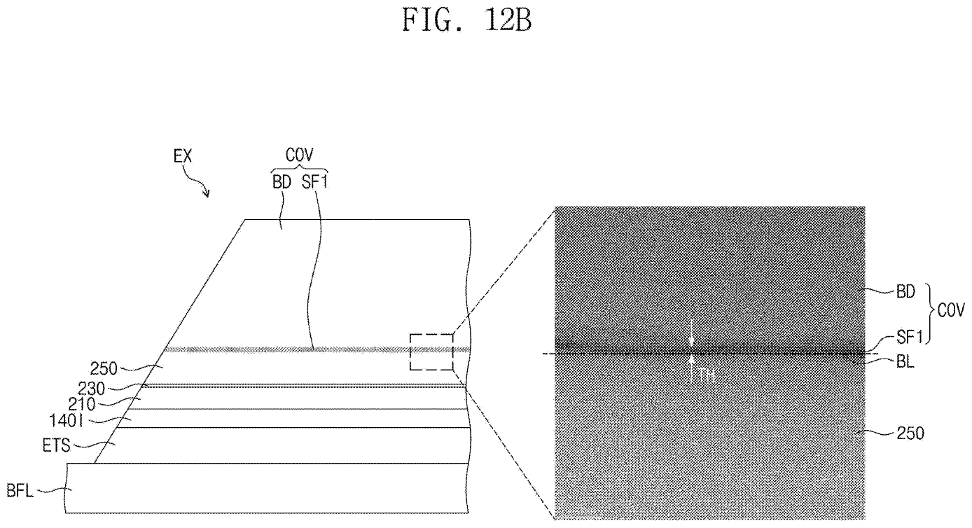

FIG. 11A is a cross-sectional view showing a boundary between a sensor cover layer and a cover layer of a display panel according to one or more embodiments of the present disclosure. FIG. 11B is a bar graph showing data for a comparative example CC and for an example EX according to embodiments of the present disclosure. FIG. 12A is a schematic cross-sectional view showing a boundary between a sensor cover layer and a cover layer of a display panel according to a comparative example. FIG. 12B is a schematic cross-sectional view showing a boundary between the sensor cover layer and the cover layer of a display panel according to one or more embodiments of the present disclosure. FIG. 11A schematically shows a process of peel strength measurement test on the cover layer COV, and FIG. 11B shows the results of peel strength measurement test. FIGS. 12A and 12B each show a transmission electron microscope (TEM) image of a boundary between a sensor cover layer and a cover layer corresponding to FIG. 11A for the comparative example CC and the example EX according to embodiments of the present disclosure, respectively. Hereinafter, the present disclosure is described with reference to FIGS. 11A to 12B.

As shown in FIG. 11A, in the peel strength measurement test between the cover layer COV and the sensor cover layer 250, the cover layer COV is formed on the sensor cover layer 250, and then the cover layer COV is peeled off by applying a force FC in a direction normal (e.g., perpendicular) to a boundary surface BDL between the sensor cover layer 250 and the cover layer COV, i.e., in the thickness direction of the cover layer COV. Here, the magnitude of the force FC by which the cover layer COV is peeled off from the sensor cover layer 250 may be measured as the peel strength.

Referring to FIGS. 12A and 12B, Comparative Example CC may include a buffer layer BFL, a barrier layer ETS, an encapsulation inorganic film 140, a sensor base layer 210, a sensor insulating layer 230, a sensor cover layer 250, and a cover layer COV-C, and may thus correspond to each of the components of the electronic panel DP shown in FIG. 10A, except for the cover layer COV-C. An embodiment of the present disclosure (hereinafter referred to as Example EX) may include a buffer layer BFL, a barrier layer ETS, an encapsulation inorganic film 140, a sensor base layer 210, a sensor insulating layer 230, a sensor cover layer 250, and a cover layer COV. For example, Example EX may have the same stacked structure as Comparison Example CC except for the cover layer COV.

Referring to FIG. 11B and FIG. 12A, Comparison Example CC shows the peel strength of about 69 mN, and Example EX shows the peel strength of about 86 mN. For example, the peel strength measured in Example EX may be greater than the peel strength measured in Comparison Example CC. Accordingly, in Comparison Example CC, a peel failure may occur between the cover layer COV-C and the sensor cover layer 250.

Referring to the TEM images, it can be seen that, unlike at the interface BL between the cover layer COV-C and the sensor cover layer 250 in Comparison Example CC shown in FIG. 12A, the first surface SF1 is formed near an interface BL between the cover layer COV and the sensor cover layer 250 in Example EX, as shown in FIG. 12B. The first surface SF1 appears darker because the first surface SF1 has a different composition from the body BD and the sensor cover layer 250 adjacent thereto. The first surface SF1 may have a certain thickness TH. As the thickness TH of the first surface SF1 increases, the coupling strength between the cover layer COV and the sensor cover layer 250 may increase. For example, as the thickness TH of the first surface SF1 increases, the peel strength of the cover layer COV may increase. The thickness TH of the first surface SF1 may be greater than about 1 nm and less than about 20 nm. According to one or more embodiments of the present disclosure, the peel strength of the cover layer COV may be controlled or selected by controlling the thickness TH of the first surface SF1.

According to one or more embodiments of the present disclosure, the peel strength of the cover layer COV may be improved by the first surface SF1. The cover layer COV includes the first surface SF1 that is in contact with the sensor cover layer 250, i.e., the interface BL with the sensor cover layer 250, and thus may not easily peel off from the sensor cover layer 250. Accordingly, the reliability of the display panel may be improved.

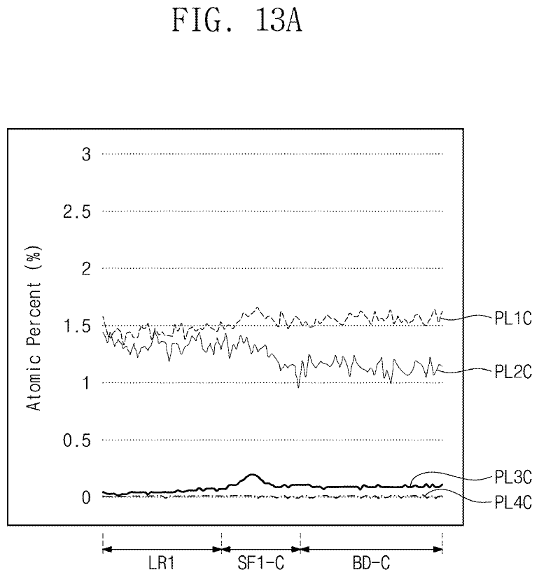

FIG. 13A is a graph showing the results of a composition analysis of the cover layer according to a comparative example, and FIG. 13B is a graph showing the results of a composition analysis of the cover layer according to one or more embodiments of the present disclosure. FIGS. 13A and 13B show the results measured by energy dispersive spectroscopy (EDS). FIG. 13A shows the results measured in Comparison Example CC shown in FIG. 12A, and FIG. 13B shows the results measured in Example EX shown in FIG. 12B.

Also, FIGS. 13A and 13B show ratios of atoms having small composition ratios, excluding carbon atoms having large composition ratios for ease of description. The first lines PL1C and PL1 on the graphs of FIGS. 13A-B illustrate the ratio of oxygen atoms (e.g., the at % of oxygen atoms relative to the total atoms in the cover layer excluding carbon), the second lines PL2C and PL2 illustrate the ratio of nitrogen atoms (e.g., the at % of nitrogen atoms relative to the total atoms in the cover layer excluding carbon), the third lines PL3C and PL3 illustrate the ratio of phosphorus atoms (e.g., the at % of phosphorus atoms relative to the total atoms in the cover layer excluding carbon), and the fourth lines PL4C and PL4 on the graphs illustrate the ratio of silicon atoms (e.g., the at % of silicon atoms relative to the total atoms in the cover layer excluding carbon).

Referring to FIG. 13A, the composition ratios may be measured sequentially along a lower layer LR1, a first surface SF1-C, and a body BD-C of Comparative Example CC. The lower layer LR1 is in contact with the first surface SF1-C and may correspond to the sensor cover layer 250 in Comparative Example CC (see, e.g., FIG. 12A). The first line PL1C, the second line PL2C, and the fourth line PL4C each show that the first surface SF1-C has a similar profile to the body BD-C. For example, the first line PL1C shows that, for oxygen atoms (O), although there are some fluctuations, the first surface SF1-C generally has about 1.5 atomic percent, which is similar to the lower layer LR1 or the body BD-C. Also, the second line PL2C shows that, for nitrogen atoms (N), the first surface SF1-C is lower than the lower layer LR1, but is similar to the body BD-C at around 1.2 atomic percent. In addition, the fourth line PL4C shows that silicon atoms (Si) are rarely found in the first surface SF1-C, which is similar to the lower layer LR1 and the body BD-C.

However, the third line PL3C shows that, for phosphorus atoms (P), the first surface SF1 has a higher ratio than the lower layer LR1 or the body BD. That is, when the cover layer COV-C is formed on the lower layer LR1, a small amount of phosphorus atoms (P) may diffuse and concentrate at the interface between the lower layer LR1 and the cover layer COV-C. However, because the ratio of phosphorus atoms (P) is not high, peeling of the cover layer COV-C may still easily occur in Comparative Example CC.

Referring to FIG. 13B, when composition ratios are measured sequentially along a lower layer LR1, a first surface SF1, and a body BD, it can be seen that the first surface SF1 according to one or more embodiments has different composition ratios from the body BD. It can be seen that, for the first to fourth lines PL1, PL2, PL3, and PL4, the first surface SF1 has different profiles from the body BD and the lower layer LR1.

For example, referring to the first line PL1, the first surface SF1 may have a higher ratio of oxygen atoms (O) than the body BD and the lower layer LR1. Also, the second line PL2 shows that, for nitrogen atoms (N), although there are some fluctuations, the first surface SF1 has about 1.8 atomic percent, which is higher than the body BD or the lower layer LR1. For example, the first surface SF1 may have a higher oxygen atom concentration and a higher nitrogen atom concentration than the body BD or the lower layer LR1.

Also, the third line PL3 shows that, for phosphorus atoms (P), the first surface SF1-C has a higher ratio than the lower layer LR1 or the body BD-C. It can be seen that the atomic percent of phosphorus atoms contained in the first surface SF1 is slightly higher than that of the first surface SF1-C in the comparison example.

Also, referring to the fourth line PL4, it can be seen that silicon atoms (Si) appear in the first surface SF1. It is found that the composition ratio of silicon atoms (Si) converges to about 0 in the body BD or the lower layer LR1, but a small amount of silicon atoms (Si) was present in the first surface SF1. The silicon may function as a leveling agent and improve the coupling strength. For example, the first surface SF1 according to one or more embodiments of the present disclosure may contain silicon atoms (Si) and thus form the interface having high coupling strength with other layers in contact therewith. Also, the cover layer COV according to one or more embodiments of the present disclosure may have improved the peel strength by providing the surface layer that contains silicon atoms, phosphorus atoms, nitrogen atoms, and oxygen atoms with higher composition ratios (e.g., higher atomic percentages) than those in the surrounding areas. Accordingly, the reliability of the display panel may be improved.

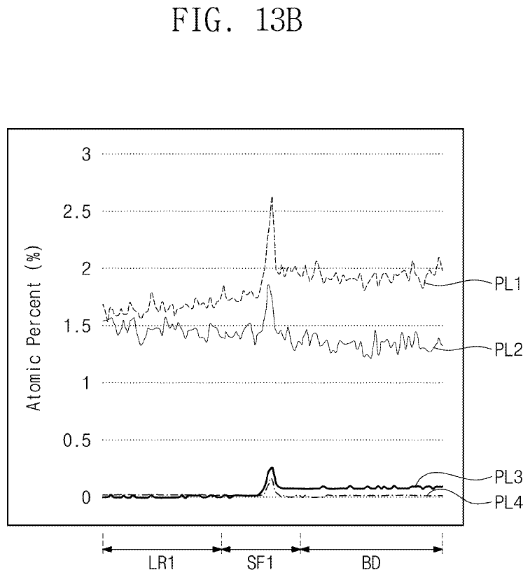

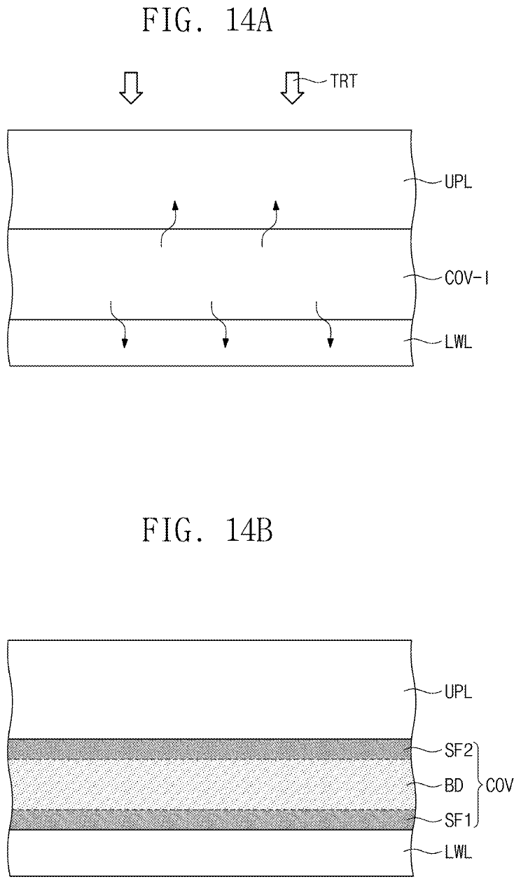

FIGS. 14A and 14B are cross-sectional views showing part of a method of manufacturing the cover layer of a display panel, according to one or more embodiments of the present disclosure. In FIGS. 14A and 14B, manufacturing of the cover layer COV is briefly illustrated for ease of description. Hereinafter, one or more embodiments of the present disclosure are described with reference to FIGS. 14A and 14B.

Referring to FIG. 14A, an initial cover layer COV-I may be formed on a lower layer LWL, and then an upper layer UPL may be formed thereon. The initial cover layer COV-I may be formed directly on the lower layer LWL and in contact with the upper surface of the lower layer LWL. The initial cover layer COV-I may be formed by an inkjet printing process. Also, the lower layer LWL may correspond to the sensor cover layer 250 (see, e.g., FIG. 8A) described above.

An upper layer UPL may be formed directly on the initial cover layer COV-I and in contact with the upper surface of the initial cover layer COV-I. The upper layer UPL may be formed by a coating process or may be formed by an inkjet printing process.

Subsequently, referring to FIGS. 14A and 14B, the initial cover layer COV-I may be formed into a cover layer COV by a curing process TRT. The curing process TRT may include a photo-curing step (e.g., act or task) and may include a UV-curing step (e.g., act or task). The curing process TRT according to one or more embodiments of the present disclosure may include an atmospheric curing process. For example, the process described above may be performed in an environment in which no additional oxygen is supplied, and UV light curing may be performed at an output of, for example, about 1.5 J and about 80 mm/sec. However, the output conditions for UV light curing are not limited thereto. For example, the curing process TRT according to one or more embodiments may include (i) an atmospheric curing process performed in an environment in which no additional oxygen is supplied, or (ii) a reduced-oxygen or inert-gas curing process (e.g., nitrogen or argon) in which oxygen is not supplied. In either case, UV light curing may be performed at an output of, for example, about 1.5 J and about 80 mm/sec.

According to one or more embodiments of the present disclosure, due to the atmospheric curing process, the surface curing speed of the initial cover layer COV-I may be reduced and the degree of curing may become lower than that of nitrogen curing (N₂ curing). Accordingly, the proportion of uncured monomer in the cover layer may increase, and leveling agents, such as silicon (Si) and phosphorus (P), among the materials constituting the initial cover layer COV-I may migrate or transfer to the surface of the initial cover layer COV-I, thereby forming a region in which the leveling agents are locally concentrated on the surface. Accordingly, the cover layer COV may be formed, which is divided into the body BD, and the first surface SF1 and the second surface SF2 having a higher composition ratio of silicon or phosphorus than the body BD.

According to one or more embodiments of the present disclosure, the peel strength of the surfaces SF1, SF2 may be controlled or selected by controlling or selecting the conditions of the curing process during the formation of the cover layer COV. Accordingly, the cover layer COV having improved interfacial coupling strength may be provided without additional processes, and the display panel having less peel failure or reduced peel failure may be provided.

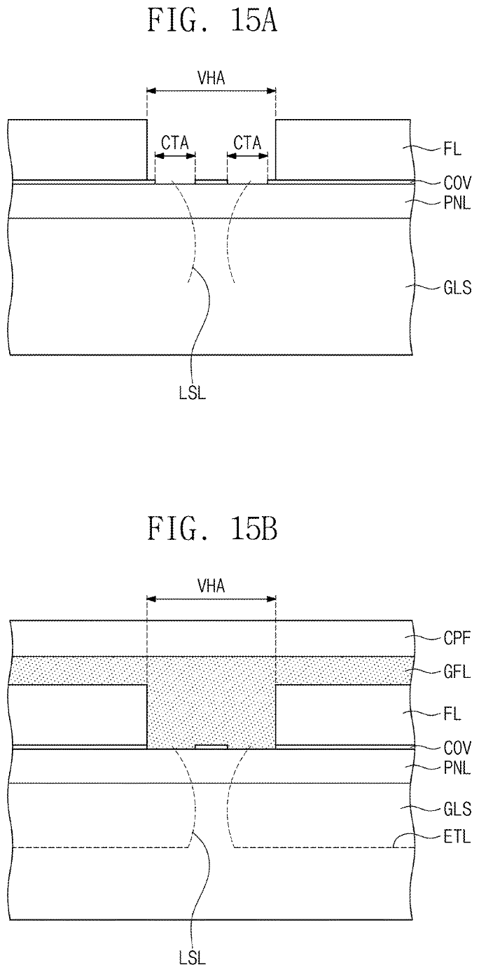

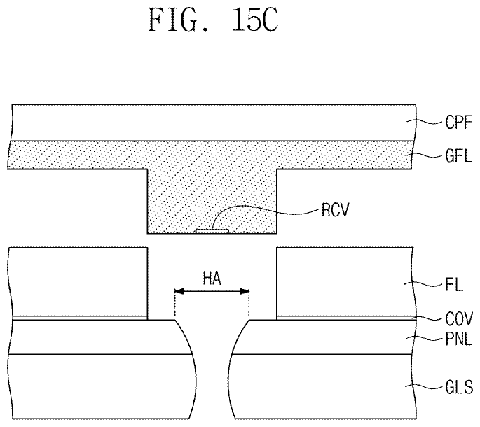

FIGS. 15A to 15C are cross-sectional views showing part of a method of manufacturing the cover layer of a display panel, according to one or more embodiments of the present disclosure. FIGS. 15A to 15C schematically illustrate a process of forming a through-hole HA in an electronic panel DP.

FIG. 15A may show a pre-ablation step (e.g., act or task). The pre-ablation step (e.g., act or task) may be a step (e.g., act or task) of using a laser to set in advance the boundary that defines a region VHA in which the hole HA is to be formed. A virtual line LSL formed by the laser is shown as a dotted line. Subsequently, in a removal step (e.g., act or task) for forming the hole HA, the hole HA may be formed by partially removing the electronic panel DP along the virtual line LSL.

Here, the electronic panel DP may be provided on a glass substrate GLS. The glass substrate GLS may include a carrier substrate. In such embodiments, after the through-hole HA is formed in the electronic panel DP, the glass substrate GLS may be removed. Also, the glass substrate GLS may include a support substrate for supporting the electronic panel DP. In such embodiments, the glass substrate GLS may be accommodated in a housing while being coupled to the electronic panel DP and may then be provided to the electronic apparatus EDE (see, e.g., FIGS. 1 to 6).

A cover layer COV and an upper layer FL may be arranged on the electronic panel DP. The upper layer FL may include at least one of the first upper layer FL1 or the second upper layer FL2 (see, e.g., FIG. 10A).

Parts of the upper layer FL and the cover layer COV that overlap the region VHA in which a through-hole is to be formed may be removed. For example, the cover layer COV may be removed by the laser that is applied during the pre-ablation step (e.g., act or task). For example, the laser may also be applied to the cover layer COV if (e.g., when) the virtual line LSL is formed in the glass substrate GLS and the electronic panel DP, thereby removing the region overlapping the virtual line LSL. Accordingly, a removal region(s) CTA overlapping the HA may be formed in the cover layer COV.

Subsequently, referring to FIG. 15B, a filler layer GFL and a cover film layer CPF may be provided on the upper layer FL. The cover film layer CPF may include a polymer film, for example, an acid-resistant film. The filler layer GFL may be formed by a coating process. Accordingly, the upper surface of the upper layer FL may be covered by the filler layer GFL, and the region VHA in which the through-hole is to be formed may be filled with the filler layer GFL. Here, an etching line ETL may be formed across part of the glass substrate GLS in the thickness direction. This line may be formed by applying laser to the glass substrate GLS and may have a shape similar to that of the virtual line LSL.

Subsequently, referring to FIG. 15C, part of a panel PNL and part of the glass substrate GLS may be removed along the virtual line LSL and the etching line ETL by an etching step (e.g., act or task). Here, the cover film layer CPF may be removed, and the filler layer GFL attached to the cover film layer CPF may be removed together. Here, some cover layer residues RCV remaining in the region VHA in which the through-hole is to be formed may be coupled to the filler layer GFL and removed together. Accordingly, the hole HA passing through the components described may be formed along the virtual line LSL.

According to one or more embodiments of the present disclosure, a pre-laser application step (e.g., act or task) in which the hole HA is formed via the pre-ablation step (e.g., act or task) is performed during the formation of the through-hole HA, and in such embodiments, the cover layer COV may be affected by the laser while being partially removed. According to one or more embodiments of the present disclosure, the cover layer COV includes the surface having a high composition ratio of silicon or phosphorus and may exhibit improved bonding strength to the panel PNL or the upper layer FL. Therefore, the interlayer peeling or lifting failure that may occur in the pre-ablation step (e.g., act or task) for forming the hole HA may be reduced, and the process reliability in the manufacture of the electronic apparatus may be improved.

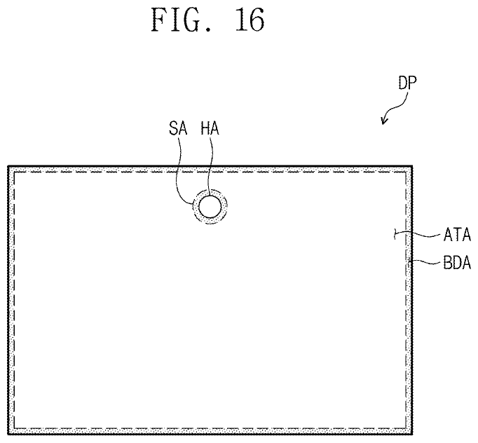

FIG. 16 is a plan view of a display panel according to one or more embodiments of the present disclosure. Referring to FIG. 16, in an electronic panel DP, a surface SF1, SF2 (see, e.g., FIG. 10A) may be selectively formed at one or more suitable positions or uniformly (e.g., substantially uniformly) formed over the entire surface. For example, the surface SF1, SF2 may be formed in a hole region SA. The hole region SA may be around (e.g., surround) a hole HA or be exposed to the outside environment. Accordingly, the hole region SA may include a region through which side surfaces of layers constituting the electronic panel DP are exposed. According to one or more embodiments of the present disclosure, the body BD (see, e.g., FIG. 10A) may be formed entirely on (e.g., formed across an entirety of) the electronic panel DP, but the surface SF1, SF2 may be formed in a closed line shape corresponding to the shape of the hole region SA. According to one or more embodiments of the present disclosure, the surface SF1, SF2 may be formed locally only in the hole region SA, and thus, the interlayer peel failure in the hole region SA may be effectively prevented or reduced during the process of forming the hole HA and subsequent processes of assembling products.

Also, for example, the surface SF1, SF2 may be formed in a bezel region BDA. The bezel region BDA may include a region around (e.g., surrounding) an active region ATA and a region through which side surfaces of layers constituting the display panel DP are exposed. According to one or more embodiments of the present disclosure, the body BD may be formed entirely on (e.g., formed across an entirety of) the electronic panel DP, but the surface SF1, SF2 may be formed in a closed line shape corresponding to the shape of the bezel region BDA. For example, the body BD may be formed entirely on the electronic panel DP, and the surface SF1 and/or SF2 may be formed in a closed line shape corresponding to the shape of the hole region SA (e.g., surrounding the through-hole in plan view). According to one or more embodiments of the present disclosure, the interlayer peel failure may be prevented or reduced by forming the surface SF1, SF2 in (e.g., only in) the bezel region BDA.

Also, the surface SF1, SF2 may be formed entirely on (e.g., formed across an entirety of) the electronic panel DP that includes the hole region SA, the active region ATA, and the bezel region BDA. According to one or more embodiments of the present disclosure, the surface SF1, SF2 having high coupling strength may be selectively formed in one or more suitable regions, thereby improving the design freedom of the electronic panel DP and providing the electronic panel DP having high reliability.

According to one or more embodiments of the present disclosure, an electronic apparatus having improved reliability may be provided.

In view of the foregoing description and accompanying drawings, it should be understood that the disclosed electronic apparatus and manufacturing method provide a multilayer panel architecture in which a cover layer includes one or more surfaces enriched with silicon and/or phosphorus relative to the body of the cover layer. These surfaces, positioned at interfaces with adjacent layers, improve interfacial adhesion and reduce peel failures, particularly in regions surrounding a through-hole for an electronic module. The specification further supports embodiments in which the sensor cover layer may be organic or inorganic, the cover layer may be formed by inkjet deposition and photo-curing under conditions where additional oxygen is not supplied, and the enriched surfaces may have a thickness of about 20 nm or less. Accordingly, the described features, variations, and manufacturing steps collectively enable an electronic apparatus having improved reliability and extended operational life.

Further, the use of “may” when describing embodiments of the present disclosure refers to “one or more embodiments of the present disclosure.”

As used herein, the term “substantially,” “about,” and similar terms are used as terms of approximation and not as terms of degree, and are intended to account for the inherent deviations in measured or calculated values that would be recognized by those of ordinary skill in the art. “Substantially” as used herein, is inclusive of the stated value and means within an acceptable range of deviation for the particular value as determined by one of ordinary skill in the art, considering the measurement in question and the error associated with measurement of the particular quantity (i.e., the limitations of the measurement system). For example, “substantially” may mean within one or more standard deviations, or within ±30%, 20%, 10%, 5% of the stated value. Also, it should be understood that, even if the terms “about,” “approximately,” or “substantially” are not expressly recited in a given element (e.g., a claim element), the scope of such element is intended to include variations that are insubstantial or within the understanding of one of ordinary skill in the art. For example, numerical values and ranges provided herein are intended to include tolerances and measurement uncertainties that would be recognized by those skilled in the art, and the elements (e.g., claim elements) should be construed accordingly to encompass such equivalents.

Also, any numerical range disclosed and/or recited herein is intended to include all sub-ranges of the same numerical precision subsumed within the recited range. For example, a range of “1.0 to 10.0” is intended to include all subranges between (and including) the recited minimum value of 1.0 and the recited maximum value of 10.0, that is, having a minimum value equal to or greater than 1.0 and a maximum value equal to or less than 10.0, such as, for example, 2.4 to 7.6. Any maximum numerical limitation recited herein is intended to include all lower numerical limitations subsumed therein and any minimum numerical limitation recited in this specification is intended to include all higher numerical limitations subsumed therein. Accordingly, Applicant reserves the right to amend this specification, including the claims, to expressly recite any sub-range subsumed within the ranges expressly recited herein.

The electronic device, device for manufacturing the display device, and/or any other relevant devices or components according to embodiments of the present disclosure described herein may be implemented utilizing any suitable hardware, firmware (e.g., an application-specific integrated circuit), software, or a combination of software, firmware, and hardware. For example, the various components of the device may be formed on one integrated circuit (IC) chip or on separate IC chips. Further, the various components of the device may be implemented on a flexible printed circuit film, a tape carrier package (TCP), a printed circuit board (PCB), or formed on one substrate. Further, the various components of the device may be a process or thread, running on one or more processors, in one or more computing devices, executing computer program instructions and interacting with other system components for performing the various functionalities described herein. The computer program instructions are stored in a memory which may be implemented in a computing device using a standard memory device, such as, for example, a random-access memory (RAM). The computer program instructions may also be stored in other non-transitory computer readable media such as, for example, a CD-ROM, flash drive, or the like. Also, a person of skill in the art should recognize that the functionality of various computing devices may be combined or integrated into a single computing device, or the functionality of a particular computing device may be distributed across one or more other computing devices without departing from the scope of the embodiments of the present disclosure.

A person of ordinary skill in the art, in view of the present disclosure in its entirety, would appreciate that each suitable feature of the various embodiments of the present disclosure may be combined or combined with each other, partially or entirely, and may be technically interlocked and operated in various suitable ways, and each embodiment may be implemented independently of each other or in conjunction with each other in any suitable manner unless otherwise stated or implied.

It will be understood that descriptions of features or aspects within each embodiment should typically be considered as available for other similar features or aspects in other embodiments, unless otherwise described. Thus, as would be apparent to one of ordinary skill in the art, features, characteristics, and/or elements described in connection with a particular embodiment may be used singly or in combination with features, characteristics, and/or elements described in connection with other embodiments unless otherwise specifically indicated. It is to be understood that the foregoing is an illustration of various example embodiments and is not to be construed as limited to the specific embodiments disclosed herein, and that various modifications to the disclosed embodiments, as well as other example embodiments, are intended to be included within the spirit and scope of the present disclosure as defined in the appended claims, and their equivalents.

What is claimed is:

1. An electronic apparatus comprising:
an electronic panel defining a through-hole; and
an electronic module overlapping the through-hole in a plan view,
wherein the electronic panel comprises:
a substrate;
a circuit element layer on the substrate;
a display element layer on the circuit element layer;
an encapsulation layer covering the display element layer;
a sensor layer on the encapsulation layer and comprising a plurality of sensor electrodes and a sensor cover layer covering the plurality of sensor electrodes; and
a cover layer on the sensor layer and comprising an organic material,
wherein the through-hole passes through the substrate, the circuit element layer, the display element layer, the encapsulation layer, the sensor layer, and the cover layer, and
wherein the cover layer comprises:
a body; and
a first surface between the body and the sensor layer and having an atomic percentage of silicon higher than that of the body.

2. The electronic apparatus of claim 1, wherein the first surface of the cover layer is in contact with the sensor cover layer.

3. The electronic apparatus of claim 2, wherein the first surface of the cover layer has an atomic percentage of silicon higher than that of the sensor cover layer.

4. The electronic apparatus of claim 1, further comprising an upper layer on the cover layer and comprising an organic material,
wherein the cover layer further comprises a second surface in contact with the upper layer and the second surface has an atomic percentage of silicon higher than that of the body.

5. The electronic apparatus of claim 4, wherein the upper layer comprises a side surface defining an opening through which the cover layer is at least partially exposed, and
the second surface of the cover layer does not overlap the opening.

6. The electronic apparatus of claim 1, wherein the first surface of the cover layer has a closed line shape surrounding the through-hole.

7. The electronic apparatus of claim 1, wherein the first surface of the cover layer has a shape completely overlapping the encapsulation layer.

8. The electronic apparatus of claim 1, wherein an atomic percentage of silicon of the body is less than or equal to 0.1 atomic percent.

9. The electronic apparatus of claim 1, wherein the first surface of the cover layer further comprises phosphorus, and
the first surface of the cover layer has an atomic percentage of phosphorus higher than that of the body.

10. The electronic apparatus of claim 1, wherein a thickness of the first surface of the cover layer is 20 nm or less.

11. The electronic apparatus of claim 1, wherein the sensor cover layer comprises an organic material.

12. The electronic apparatus of claim 1, further comprising at least one of a processor, memory, or a power module.

13. The electronic apparatus of claim 1, wherein the electronic apparatus is a television, a monitor, an outdoor advertising board, a personal computer (PC), a laptop computer, a personal digital terminal, an automobile instrument panel, a center fascia, a navigation unit, a room mirror display, a game console, a smartphone, a tablet PC, a smart watch, smart glasses, a head-mounted display, or a camera.

14. An electronic apparatus comprising:
an electronic panel defining a through-hole; and
an electronic module overlapping the through-hole in a plan view,
wherein the electronic panel comprises:
a substrate;
a circuit element layer on the substrate;
a display element layer on the circuit element layer;
an encapsulation layer covering the display element layer;
a sensor layer on the encapsulation layer and comprising a plurality of sensor electrodes and a sensor cover layer covering the plurality of sensor electrodes;
a cover layer on the sensor layer; and
an upper layer on the cover layer,
wherein the through-hole passes through the substrate, the circuit element layer, the display element layer, the encapsulation layer, the sensor layer, and the cover layer, and
wherein the cover layer comprises:
a body comprising an organic material;
a first surface below the body and in contact with the sensor cover layer, the first surface having an atomic percentage of silicon higher than that of the body; and
a second surface above the body and in contact with the upper layer, the second surface having an atomic percentage of silicon higher than that of the body.

15. The electronic apparatus of claim 14, wherein the upper layer comprises an organic material.

16. The electronic apparatus of claim 14, wherein the first surface and the second surface of the cover layer each have different shapes from the body in the plan view.

17. The electronic apparatus of claim 16, wherein the first surface and the second surface of the cover layer each be around the through-hole in the plan view.

18. The electronic apparatus of claim 14, wherein the first surface and the second surface of the cover layer each further comprise phosphorus, and
the first surface and the second surface of the cover layer each have an atomic percentage of phosphorus higher than the body.

19. A method comprising:
forming, on a substrate, a display element layer comprising an organic light-emitting element;
forming an encapsulation layer on the display element layer;
forming a plurality of sensor electrodes on the encapsulation layer;
forming a sensor cover layer covering the plurality of sensor electrodes;
forming an organic film on the sensor cover layer; and
photo-curing the organic film so that a first surface is formed at a boundary surface between the sensor cover layer and a region of the organic film which is in contact with the sensor cover layer,
wherein, in the photo-curing of the organic film, additional oxygen is not supplied, and
wherein the method is a method of manufacturing an electronic apparatus.

20. The method of claim 19, wherein the forming of the organic film comprises an inkjet printing process.
